(19) United States
(12) Patent Application Publication
(10) Pub. No.: US 2026/0128724 A1
(43) Pub. Date: May 7, 2026

(54) FILTER APPARATUS

(71) Applicant: Murata Manufacturing Co., Ltd., Nagaokakyo-shi (JP)

(72) Inventors: Yasunobu HAYASHI, Nagaokakyo-shi (JP); Yasumasa TANIGUCHI, Nagaokakyo-shi (JP)

(21) Appl. No.: 19/437,428

(22) Filed: Dec. 31, 2025

Related U.S. Application Data
(63) Continuation of application No. PCT/JP2024/022942, filed on Jun. 25, 2024.

(30) Foreign Application Priority Data
Jul. 26, 2023 (JP) 2023-121295

(51) Int. Cl. H03H 9/145; H03H 9/64

(52) U.S. Cl. CPC H03H 9/145; H03H 9/6483

(57) ABSTRACT

A filter apparatus includes a first piezoelectric substrate including first and second main surfaces, a first resonator including a functional electrode on the first main surface, a second piezoelectric substrate including third and fourth main surfaces, a second resonator including a functional electrode on the third main surface, a support between the first and third main surfaces and providing a space between the first and third main surfaces, and a through electrode passing through the first piezoelectric substrate and electrically coupled to one of the first and second resonators. A thickness of the first piezoelectric layer is smaller than a thickness of the second piezoelectric layer.

### CROSS REFERENCE TO RELATED APPLICATIONS

This application claims the benefit of priority to Japanese Patent Application No. 2023-121295 filed on Jul. 26, 2023 and is a Continuation Application of PCT Application No. PCT/JP 2024/022942 filed on Jun. 25, 2024. The entire contents of each application are hereby incorporated herein by reference.

### BACKGROUND OF THE INVENTION

### 1. Field of the Invention

The present invention relates to filter apparatuses each including multiple acoustic wave resonators.

### 2. Description of the Related Art

Heretofore, filter apparatuses including acoustic wave resonators have been widely used as filters for mobile phones and the like. International Publication No. WO2006/008940 discloses an example of a piezoelectric filter as a filter apparatus. In this piezoelectric filter, a pair of piezoelectric substrates are bonded together with a bonding layer. A hollow space is formed between the pair of piezoelectric substrates. An interdigital transducer (IDT) and electrode pads are provided on a main surface of each of the piezoelectric substrates so as to be located in the hollow space.

In one of the substrates, through holes are provided so as to pass through the substrate. One end portion of each through hole is coupled to an outer electrode. The other end portion of the through hole is coupled to the electrode pad.

In order to form through holes in manufacturing of the piezoelectric filter described in International Publication No. WO2006/008940, the through holes are provided in the piezoelectric substrate. The electrode pads are used as stoppers in the process of forming the through holes. However, in reality, the electrode pads tend to be worn out during the process of forming the through holes. For this reason, the reliability of the piezoelectric filter may deteriorate.

### SUMMARY OF THE INVENTION

Example embodiments of the present invention provide filter apparatuses each able to reduce or prevent deterioration of reliability.

A filter apparatus according to an example embodiment of the present invention includes a first piezoelectric substrate including a first main surface and a second main surface opposed to each other, at least one first resonator including a functional electrode on the first main surface, a second piezoelectric substrate including a third main surface located on a first piezoelectric substrate side and a fourth main surface opposed to the third main surface, at least one second resonator including a functional electrode on the third main surface, a support between the first main surface and the third main surface and defining a space between the first main surface and the third main surface, and a through electrode passing through the first piezoelectric substrate and electrically coupled to any one of the at least one first resonator and the at least one second resonator. The first piezoelectric substrate includes a first supporting substrate and a first piezoelectric layer stacked on the first supporting substrate, the first main surface including a main surface of the first piezoelectric layer. The second piezoelectric substrate includes a second supporting substrate and a second piezoelectric layer stacked on the second supporting substrate, the third main surface including a main surface of the second piezoelectric layer. A thickness of the first piezoelectric layer is less than a thickness of the second piezoelectric layer.

Filter apparatuses according to example embodiments of the present invention are each able to reduce or prevent deterioration of reliability.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational sectional view of a filter apparatus according to a first example embodiment of the present invention.

FIGS. 2A and 2B are schematic elevational sectional views illustrating steps for providing through electrodes in a piezoelectric substrate in the first example embodiment of the present invention.

FIGS. 3A and 3B are schematic elevational sectional views illustrating steps of forming through holes in a piezoelectric substrate in order to provide the through electrodes in the piezoelectric substrate in the first example embodiment of the present invention.

FIG. 4 is a schematic plan view of a first resonator in the first example embodiment of the present invention.

FIG. 5 is a schematic plan view for explaining the widths and others of the through electrodes.

FIG. 6 is a diagram showing a relationship between the thickness of the piezoelectric layer and TCFa in the resonator in the first example embodiment of the present invention.

FIG. 7 is a diagram showing a relationship between the thickness of the piezoelectric layer and TCFr in the resonator in the first example embodiment of the present invention.

FIG. 8 is a schematic diagram of frequency characteristics of impedances of a series arm resonator and a parallel arm resonator.

FIG. 9 is a schematic diagram of frequency characteristics of an attenuation of a band pass filter.

FIG. 10 is a schematic plan view of a first resonator in a first modification of the first example embodiment of the present invention.

FIG. 11 is a schematic plan view of a through electrode in a second modification of the first example embodiment of the present invention.

FIGS. 12A to 12C are schematic elevational sectional views illustrating steps for providing through electrodes in a piezoelectric substrate in the second modification of the first example embodiment of the present invention.

FIGS. 13A and 13B are schematic elevational sectional views illustrating an example of steps after the through electrodes are provided in the piezoelectric substrate in the second modification of the first example embodiment of the present invention.

FIG. 14 is a schematic elevational sectional view of a filter apparatus according to a third modification of the first example embodiment of the present invention.

FIG. 15 is a schematic elevational sectional view of a filter apparatus according to a fourth modification of the first example embodiment of the present invention.

FIG. 16 is a schematic diagram of VSWR (Voltage Standing Wave Ratio) in a second example embodiment of the present invention.

FIG. 17 is a schematic elevational sectional view of a filter apparatus according to a third example embodiment of the present invention.

FIG. 18 is a diagram showing a relationship between a cut-angle of a piezoelectric layer and a fractional bandwidth in a resonator in the third example embodiment of the present invention.

FIG. 19 is a schematic diagram of frequency characteristics of impedances of a series arm resonator and a parallel arm resonator in the third example embodiment of the present invention.

FIG. 20 is a schematic diagram of frequency characteristics of an attenuation of the filter apparatus in the third example embodiment of the present invention.

FIG. 21 is a schematic elevational sectional view of a filter apparatus according to a fifth example embodiment of the present invention.

FIG. 22 is a diagram showing a relationship between the thickness of an intermediate layer and a fractional bandwidth in a resonator in the fifth example embodiment of the present invention.

FIG. 23 is a diagram showing a relationship among the thickness of a piezoelectric layer, the thickness of an intermediate layer, and the phase of harmonic waves.

FIG. 24 is a schematic elevational sectional view of a filter apparatus according to a sixth example embodiment of the present invention.

FIG. 25 is a schematic elevational sectional view for explaining an advantageous effect in the sixth example embodiment of the present invention.

FIG. 26 is a schematic elevational sectional view of a filter apparatus according to a seventh example embodiment of the present invention.

FIG. 27 is a schematic elevational sectional view for explaining an advantageous effect in the seventh example embodiment of the present invention.

FIG. 28 is a schematic elevational sectional view of a filter apparatus according to an eighth example embodiment of the present invention.

FIG. 29 is a diagram showing a relationship between ψ in Euler angles (φ, θ, ψ) of a supporting substrate and the phases of Rayleigh waves and harmonic waves.

FIG. 30 is a diagram showing the relationship shown in FIG. 29 in a case where the phase is about −60° or less.

FIG. 31 is a schematic elevational sectional view of a filter apparatus according to a tenth example embodiment of the present invention.

FIG. 32 is a diagram showing a relationship between the thickness of an IDT electrode and TCFa.

FIG. 33 is a diagram showing a relationship between the thickness of the IDT electrode and TCFr.

FIG. 34 is a schematic plan view illustrating a layout of resonators on a first main surface of a first piezoelectric substrate in a 12th example embodiment of the present invention.

FIG. 35 is a schematic see-through plan view illustrating a layout of resonators on a third main surface of a second piezoelectric substrate in the 12th example embodiment of the present invention.

FIG. 36 is a schematic elevational sectional view of a filter apparatus according to a 13th example embodiment of the present invention.

FIG. 37 is a diagram showing a relationship between the thickness of a dielectric film and a fractional bandwidth.

FIG. 38 is a schematic elevational sectional view of a filter apparatus according to a 14th example embodiment of the present invention.

FIG. 39 is a schematic elevational sectional view of an acoustic wave device according to a 15th example embodiment of the present invention.

FIG. 40 is a schematic elevational sectional view of an acoustic wave device according to a 16th example embodiment of the present invention.

FIG. 41 is a schematic elevational sectional view of an acoustic wave device according to a 17th example embodiment of the present invention.

FIG. 42 is a schematic elevational sectional view of an acoustic wave device according to an 18th example embodiment of the present invention.

FIG. 43 is a schematic elevational sectional view of an acoustic wave device according to a 19th example embodiment of the present invention.

### DETAILED DESCRIPTION OF THE EXAMPLE EMBODIMENTS

The present invention will be clarified below by explaining example embodiments of the present invention with reference to the drawings.

All of the example embodiments described herein are merely illustrative, and a structure in an example embodiment may be partially replaced or combined with a structure in any of the other example embodiments.

The filter apparatuses according to example embodiments of the present invention may be a band pass filter including one pass band or may be a composite filter apparatus including multiple pass bands. In an example where a filter apparatus is a band pass filter, the filter apparatus may be, for example, a transmit filter or a receive filter. In an example where a filter apparatus is a composite filter apparatus, the filter apparatus may be, for example, a multiplexer such as a duplexer, a triplexer, or a quadplexer.

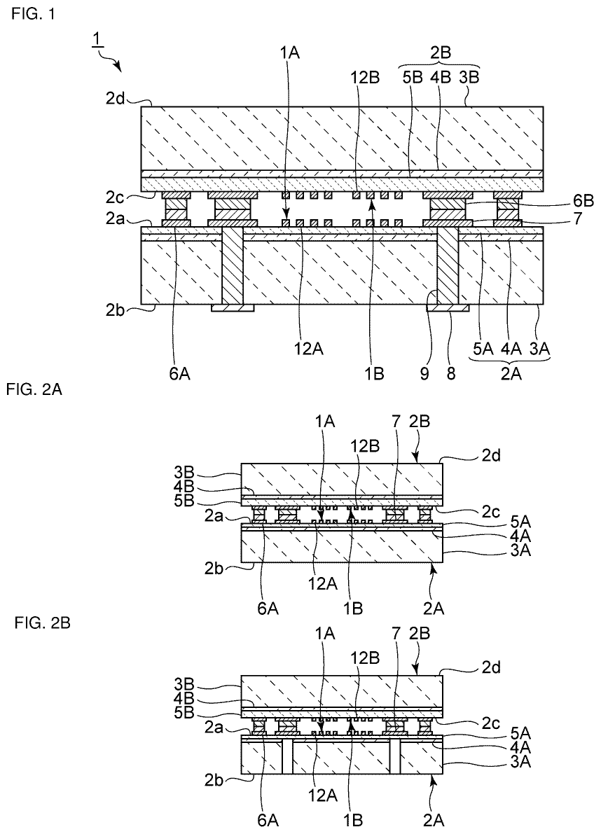

FIG. 1 is a schematic elevational sectional view of a filter apparatus according to a first example embodiment of the present invention. In FIG. 1, reflectors to be described later are omitted. Similarly, reflectors are omitted in schematic elevational sectional views other than FIG. 1.

A filter apparatus 1 in the present example embodiment is a band pass filter. Specifically, the filter apparatus 1 is a ladder filter. The filter apparatus 1 includes multiple series arm resonators and multiple parallel arm resonators. However, in the case where the filter apparatus 1 is a ladder filter, it is sufficient that the filter apparatus 1 includes at least one series arm resonator and at least one parallel arm resonator.

As illustrated in FIG. 1, the filter apparatus 1 includes a first piezoelectric substrate 2A and a second piezoelectric substrate 2B. The piezoelectric substrate is a substrate with piezoelectricity. The first piezoelectric substrate 2A includes a first supporting substrate 3A, a first intermediate layer 4A, and a first piezoelectric layer 5A. The first intermediate layer 4A is provided on the first supporting substrate 3A. The first piezoelectric layer 5A is provided on the first intermediate layer 4A.

The first piezoelectric substrate 2A includes a first main surface 2a and a second main surface 2b. The first main surface 2a and the second main surface 2b are opposed to each other. The first main surface 2a is specifically a main surface in the first piezoelectric substrate 2A that is located closest to the second piezoelectric substrate 2B. In the present example embodiment, a main surface of the first piezoelectric layer 5A is the first main surface 2a. However, it is sufficient that the first main surface 2a includes at least the main surface of the first piezoelectric layer 5A. For example, the first main surface 2a may include the main surface of the first piezoelectric layer 5A and a main surface of the first intermediate layer 4A or a main surface of the first supporting substrate 3A.

On the other hand, the second main surface 2b of the first piezoelectric substrate 2A is a main surface opposed to the first main surface 2a, and located outermost in the first piezoelectric substrate 2A. Thus, the second main surface 2b is the main surface of the first supporting substrate 3A that is located outermost in the first piezoelectric substrate 2A.

Similarly, the second piezoelectric substrate 2B is a multilayer substrate including a second supporting substrate 3B, a second intermediate layer 4B, and a second piezoelectric layer 5B. A third main surface 2c of the second piezoelectric substrate 2B is a main surface in the second piezoelectric substrate 2B that is located closest to the first piezoelectric substrate 2A. In the present example embodiment, a main surface of the second piezoelectric layer 5B is the third main surface 2c. However, it is sufficient that the third main surface 2c includes at least the main surface of the second piezoelectric layer 5B. For example, the third main surface 2c may include the main surface of the second piezoelectric layer 5B and a main surface of the second intermediate layer 4B or a main surface of the second supporting substrate 3B.

On the other hand, a fourth main surface 2d of the second piezoelectric substrate 2B is a main surface opposed to the third main surface 2c, and located outermost in the second piezoelectric substrate 2B. Thus, the fourth main surface 2d is the main surface of the second supporting substrate 3B that is located outermost in the second piezoelectric substrate 2B.

In the present example embodiment, for example, silicon is used as a material for the first supporting substrate 3A and the second supporting substrate 3B. Silicon oxide, for example, is used as a material for the first intermediate layer 4A and the second intermediate layer 4B. However, the materials for the above-described layers are not limited to the above.

Multiple first resonators 1A are provided on the first piezoelectric substrate 2A. Specifically, multiple functional electrodes are provided on the first main surface 2a of the first piezoelectric substrate 2A. Each of the multiple first resonators 1A includes a functional electrode. More specifically, in the present example embodiment, each of the functional electrodes provided on the first piezoelectric substrate 2A is a first IDT electrode 12A.

A first support 6A, which defines and functions as a support, is provided on the first main surface 2a of the first piezoelectric substrate 2A. The first support 6A has a frame shape. The first support 6A is provided so as to surround the multiple first resonators 1A provided on the first piezoelectric substrate 2A. More specifically, the first support 6A surrounds the multiple functional electrodes provided on the first main surface 2a.

Multiple electrode pads 7 are provided on the first main surface 2a of the first piezoelectric substrate 2A. A second support 6B is provided on each of the multiple electrode pads 7. Each second support 6B has a columnar shape. Here, the multiple second supports 6B are surrounded by the first support 6A.

The second piezoelectric substrate 2B is provided on the first support 6A and on the multiple second supports 6B. Thus, a space is provided between the first main surface 2a of the first piezoelectric substrate 2A and the third main surface 2c of the second piezoelectric substrate 2B. In the present example embodiment, the space is sealed by the first piezoelectric substrate 2A, the second piezoelectric substrate 2B, and the first support 6A.

Multiple second resonators 1B are provided on the second piezoelectric substrate 2B. Specifically, multiple functional electrodes are provided on the third main surface 2c of the second piezoelectric substrate 2B. More specifically, in the present example embodiment, each of the functional electrodes provided on the second piezoelectric substrate 2B is a second IDT electrode 12B.

The filter apparatus 1 is a ladder filter including the multiple first resonators 1A and the multiple second resonators 1B. It is sufficient that the multiple first resonators 1A and the multiple second resonators 1B include at least one series arm resonator and at least one parallel arm resonator.

As illustrated in FIG. 1, the filter apparatus 1 is configured as a two-substrate stack including the first piezoelectric substrate 2A and the second piezoelectric substrate 2B. Instead, the filter apparatus according to the present invention may be configured as a three or more-substrate stack.

Multiple outer coupling terminals 8 are provided on the second main surface 2b of the first piezoelectric substrate 2A. Multiple through electrodes 9 are provided so as to pass through the first piezoelectric substrate 2A. One end portion of each through electrode 9 is coupled to one of the electrode pads 7. The other end portion of each through electrode 9 is coupled to one of the outer coupling terminals 8. On the other hand, the second piezoelectric substrate 2B is not provided with any through electrode 9.

Each of the multiple first resonators 1A and the multiple second resonators 1B is electrically coupled to the electrode pad 7. Each of the multiple first resonators 1A and the multiple second resonators 1B is electrically coupled to outside via the electrode pad 7, the through electrode 9, and the outer coupling terminal 8. Here, the multiple electrode pads 7 may include an electrode pad 7 not coupled to any of the through electrodes 9.

In the present example embodiment, the through electrodes 9 are provided in the first piezoelectric substrate 2A and a thickness of the first piezoelectric layer 5A of the first piezoelectric substrate 2A is less than a thickness of the second piezoelectric layer 5B of the second piezoelectric substrate 2B. These features make it possible to reduce or prevent deterioration of the reliability of the filter apparatus 1. The above-described advantageous effects will be described below in detail together with some operations, related to the above-described advantageous effects, in an example of a method for manufacturing the filter apparatus 1.

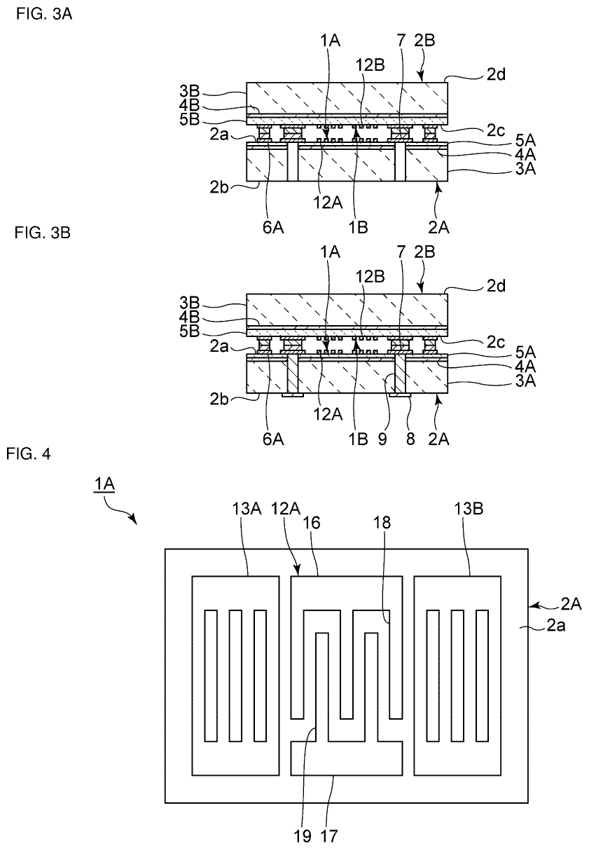

FIGS. 2A and 2B are schematic elevational sectional views illustrating steps for providing through electrodes in a piezoelectric substrate in the first example embodiment. FIGS. 3A and 3B are schematic elevational sectional views illustrating steps of forming through holes in the piezoelectric substrate in order to provide the through electrodes in the piezoelectric substrate in the first example embodiment.

As illustrated in FIG. 2A, a two-substrate stack is prepared in which the first piezoelectric substrate 2A and the second piezoelectric substrate 2B are bonded together with the first support 6A. Here, multiple functional electrodes are provided on each of the first main surface 2a of the first piezoelectric substrate 2A and the third main surface 2c of the second piezoelectric substrate 2B. The multiple electrode pads 7 are provided on the first main surface 2a of the first piezoelectric substrate 2A.

Next, as illustrated in FIG. 2B, through holes are formed in the first supporting substrate 3A and the first intermediate layer 4A in the first piezoelectric substrate 2A. In an example where silicon is used as the material for the first supporting substrate 3A as in the present example embodiment, the Bosch process or the like, for example, is preferably used for forming the through holes in the first supporting substrate 3A. In the Bosch process, isotropic etching, protective film formation, and anisotropic etching are repeated. As a result of this process, each hole formed in the first supporting substrate 3A has a high aspect ratio. The through holes can also be formed in the first intermediate layer 4A by etching.

Next, as illustrated in FIG. 3A, through holes are formed in the first piezoelectric layer 5A so as to extend to the electrode pads 7. For forming the through holes in the first piezoelectric layer 5A, dry etching using, for example, Ar as a main etchant is used. In this etching, the electrode pads 7 define and function as etching stopper layers.

Next, as illustrated in FIG. 3B, the through electrodes 9 are provided in the through holes so that one end portions thereof are coupled to the electrode pads 7. Simultaneously, the outer coupling terminals 8 are provided on the second main surface 2b of the first piezoelectric substrate 2A. Specifically, it is sufficient that, for example, after a seed layer is formed in the through holes and on the second main surface 2b, the through electrodes 9 and the outer coupling terminals 8 are provided by plating.

In the present example embodiment, the first piezoelectric layer 5A has a small thickness. Such small thickness makes it possible to shorten an etching time for forming the through holes in the first piezoelectric layer 5A. Accordingly, it is possible to shorten a time for which the electrode pads 7 are etched. This can reduce or prevent damage to the electrode pads 7. Specifically, for example, it is possible to prevent a crack from occurring in the electrode pads 7. This makes it possible to reduce or prevent moisture from entering the space between the first piezoelectric substrate 2A and the second piezoelectric substrate 2B through a crack or the like. Therefore, it is possible to reduce or prevent deterioration of the reliability of the filter apparatus 1.

Hereinafter, the structure in the present example embodiment will be described in more details.

FIG. 4 is a schematic plan view of a first resonator in the first example embodiment.

The first resonator 1A includes a first IDT electrode 12A and a pair of a reflector 13A and a reflector 13B. The first IDT electrode 12A, the reflector 13A, and the reflector 13B are provided on the first main surface 2a of the first piezoelectric substrate 2A.

The first IDT electrode 12A includes a pair of busbars and multiple electrode fingers. Specifically, the pair of the busbars include a first busbar 16 and a second busbar 17. The first busbar 16 and the second busbar 17 are opposed to each other. The multiple electrode fingers specifically include multiple first electrode fingers 18 and multiple second electrode fingers 19. One end portions of the multiple first electrode fingers 18 are coupled to the first busbar 16. One end portions of the multiple second electrode fingers 19 are coupled to the second busbar 17. The multiple first electrode fingers 18 and the multiple second electrode fingers 19 are interdigitated with each other. The first electrode fingers 18 and the second electrode fingers 19 are coupled to respective potentials different from each other.

Each of the first resonators 1A other than the first resonator 1A illustrated in FIG. 4 similarly includes a first IDT electrode 12A and a pair of reflectors. Each second resonator 1B includes a second IDT electrode 12B and a pair of reflectors. The second IDT electrode 12B also includes a pair of busbars and multiple electrode fingers as in the first IDT electrode 12A. It is sufficient that each first IDT electrode 12A, each second IDT electrode 12B, and each reflector have appropriate design parameters according to desired electrical characteristics.

In the filter apparatus 1 in the present example embodiment, each first resonator 1A and each second resonator 1B are, for example, one-port surface acoustic wave resonators.

When an AC voltage is applied to the first IDT electrode 12A, acoustic waves are excited. In the first IDT electrode 12A, an acoustic wave propagation direction is orthogonal or substantially orthogonal to an electrode finger extension direction, which is defined as a direction in which the multiple electrode fingers extend. The same applies to all of the first IDT electrodes 12A. In the present example embodiment, all of the first IDT electrodes 12A have the same acoustic wave propagation direction.

Similarly, when an AC voltage is applied to the second IDT electrode 12B, acoustic waves are excited. In the second IDT electrode 12B, an acoustic wave propagation direction is orthogonal or substantially orthogonal to an electrode finger extension direction, which is defined as a direction in which the multiple electrode fingers extend. The same applies to all of the second IDT electrodes 12B. In the present example embodiment, all of the second IDT electrodes 12B have the same acoustic wave propagation direction. In the present example embodiment, in plan view, all the first IDT electrodes 12A and all the second IDT electrodes 12B have the same acoustic wave propagation direction.

In the present description, “plan view” refers to viewing from a direction corresponding to an upper side in FIG. 1. In FIG. 1, for example, of a first piezoelectric substrate 2A side and a second piezoelectric substrate 2B side, the second piezoelectric substrate 2B side is the upper side.

The first support 6A and the multiple second supports 6B are made of appropriate metals. The first resonators 1A and the second resonators 1B are electrically coupled to each other via the first support 6A and the multiple second supports 6B. In this way, a circuit of the filter apparatus 1 is configured.

In a case where λ denotes a wavelength determined by an electrode finger pitch, the thickness of the first piezoelectric layer 5A is, for example, about 0.2λ in the present example embodiment. The thickness of the second piezoelectric layer 5B is, for example, about 0.35λ. More specifically, the wavelength λ, which is used as a basis for the thicknesses of the first piezoelectric layer 5A and the second piezoelectric layer 5B, is the shortest wavelength λ among wavelengths λ of all of the first IDT electrodes 12A and all of the second IDT electrodes 12B. The same applies to the thicknesses of the layers in the first piezoelectric substrate 2A and the second piezoelectric substrate 2B other than the above layers, the first IDT electrodes 12A, and the second IDT electrodes 12B. The electrode finger pitch is defined as an inter-center distance, in the acoustic wave propagation direction, between adjacent electrode fingers coupled to the respective potentials different from each other.

The thickness of the first piezoelectric layer 5A and the thickness of the second piezoelectric layer 5B are not limited to the above. However, the thickness of the first piezoelectric layer 5A is, for example, preferably smaller than about 5 μm. Such small thickness makes it possible to more surely prevent a crack from occurring after the through holes are formed in the first piezoelectric layer 5A. Therefore, the reliability of the filter apparatus can be effectively improved.

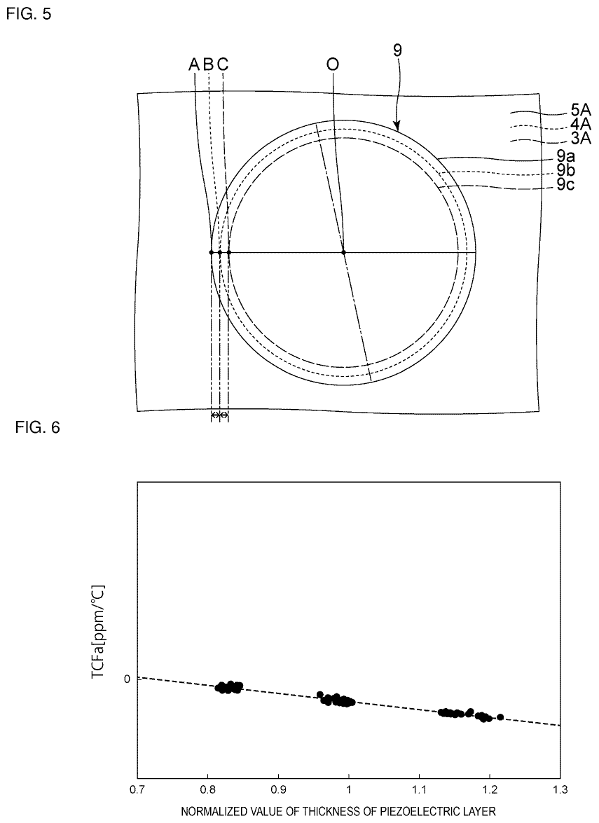

FIG. 5 is a schematic plan view for explaining the widths and others of the through electrode.

In the following description, the width of the through electrode 9 is defined as a dimension of a line passing through the center O of the through electrode 9 and two points on the outer circumference of the through electrode 9 in plan view, as illustrated by a dashed-dotted line in FIG. 5.

In the present example embodiment, the widest width of a portion of the through electrode 9 passing through the first piezoelectric layer 5A is, for example, less than about 100 μm. In this case, the widest width of the through hole in the first piezoelectric layer 5A is, for example, also less than about 100 μm. Such widths make it possible to more surely prevent a crack from occurring after the through holes are formed in the first piezoelectric layer 5A.

Here, it is preferable that the widest width of the portion of the through electrode 9 passing through the first piezoelectric layer 5A is, for example, about 10 μm or more. In this case, the electrical resistance of the through electrode 9 can be suitably maintained low.

Returning to FIG. 3B, the through electrodes 9 are provided in the first piezoelectric substrate 2A after the first piezoelectric substrate 2A and the second piezoelectric substrate 2B are bonded together with the first support 6A. In this case, in the through electrode 9, there are small differences among the width of a portion passing through the first supporting substrate 3A, the width of a portion passing through the first intermediate layer 4A, and the width of a portion passing through the first piezoelectric layer 5A.

More specifically, as schematically illustrated in FIG. 5, in plan view, an outer circumferential edge of the portion of the through electrode 9 passing through the first piezoelectric layer 5A is referred to as a first outer circumferential edge 9a, and an outer circumferential edge of the portion of the through electrode 9 passing through the first intermediate layer 4A is referred to as a second outer circumferential edge 9b. A point at which a line drawn from the center O of the through electrode 9 intersects the first outer circumferential edge 9a is referred to as a first point A, and a point at which the above line intersects the second outer circumferential edge 9b is referred to as a second point B. A dimension defined as the distance between the first point A and the second point B is equal to or less than a dimension defined as the thickness of the first intermediate layer 4A.

An outer circumferential edge of the portion of the through electrode 9 passing through the first supporting substrate 3A is referred to as a third outer circumferential edge 9c. The point at which the line drawn from the center O of the through electrode 9 intersects the first outer circumferential edge 9a is referred to as the first point A, and a point at which the above line intersects the third outer circumferential edge 9c is referred to as a third point C. A dimension defined as the distance between the first point A and the third point C is equal to or less than a dimension defined as the total of the thickness of the first piezoelectric layer 5A and the thickness of the first intermediate layer 4A.

In the present example embodiment, all of the first resonators 1A included in the filter apparatus 1 are series arm resonators. At the same time, all of the series arm resonators in the filter apparatus 1 are the first resonators 1A. Then, in these series arm resonators, the thicknesses of the piezoelectric layers are small. This structure makes it possible to reduce or prevent deterioration of the filter characteristics. This advantageous effect will be described below in detail.

In the present description, the first resonators 1A and the second resonators 1B will be collectively simply referred to as a resonator in some cases. The first piezoelectric layer 5A and the second piezoelectric layer 5B will be collectively simply referred to as a piezoelectric layer in some cases. The first intermediate layer 4A and the second intermediate layer 4B will be collectively simply referred to as an intermediate layer in some cases. The first supporting substrate 3A and the second supporting substrate 3B will be collectively simply referred to as a supporting substrate in some cases. The first IDT electrodes 12A and the second IDT electrodes 12B will be collectively simply referred to as an IDT electrode. In the following description, a temperature coefficient of frequency at resonant frequency will be abbreviated as TCFr. A temperature coefficient of frequency at anti-resonant frequency will be abbreviated as TCFa.

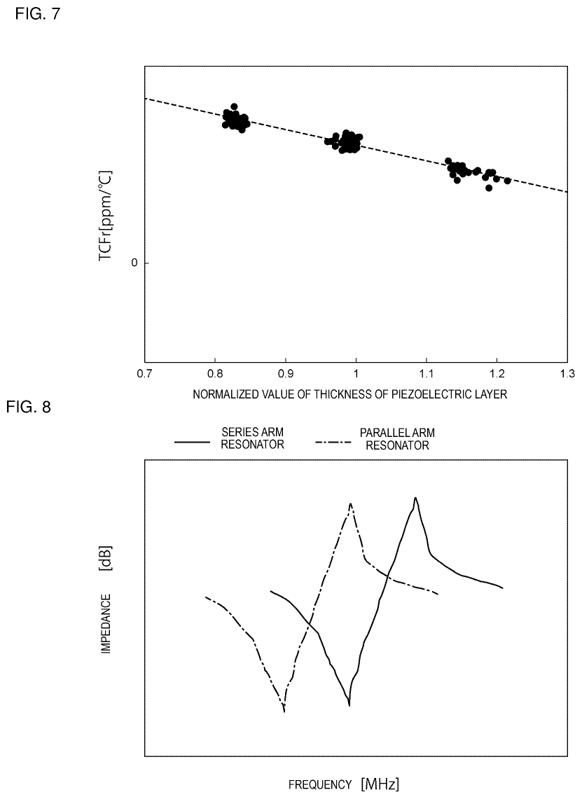

FIG. 6 is a diagram showing a relationship between the thickness of the piezoelectric layer and TCFa in the resonator in the first example embodiment. FIG. 7 is a diagram showing a relationship between the thickness of the piezoelectric layer and TCFr in the resonator in the first example embodiment. In FIGS. 6 and 7, the thickness of the piezoelectric layer is shown as a normalized value. In the present description, the normalized value refers to a value normalized with a certain standard set to 1.

As shown in FIG. 6, the larger the thickness of the piezoelectric layer, the greater TCFa becomes in a negative direction. Since the thickness of the first piezoelectric layer 5A in the first resonator 1A is small, TCFa can be made approximately 0 ppm/° C.

As shown in FIG. 7, the larger the thickness of the piezoelectric layer, the greater TCFr becomes in the negative direction. Since the thickness of the second piezoelectric layer 5B in the second resonator 1B is large, TCFr can be made a value close to 0 ppm/° C.

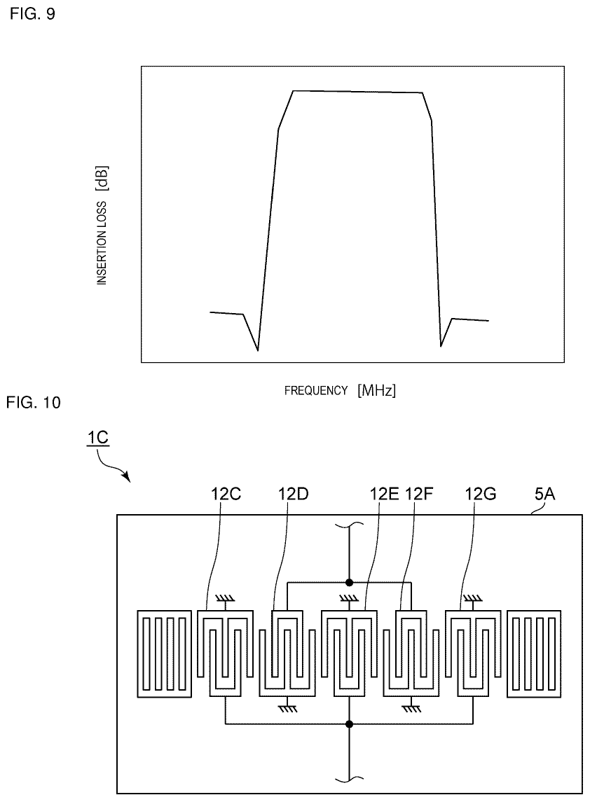

FIG. 8 is a schematic diagram of frequency characteristics of impedances of a series arm resonator and a parallel arm resonator. FIG. 9 is a schematic diagram of frequency characteristics of an attenuation of a band pass filter.

As shown in FIGS. 8 and 9, a pass band of the band pass filter is provided at the resonant frequency of the series arm resonator. On the other hand, the anti-resonant frequency of the series arm resonator is a frequency higher than the pass band. However, if the anti-resonant frequency is close to the pass band, the insertion loss of the band pass filter may be large. Here, when the series arm resonator operates, the temperature of the series arm resonator rises. If TCFa of the series arm resonator is a negative value, the anti-resonant frequency of the series arm resonator becomes closer to the pass band of the band pass filter as the temperature rises.

In contrast to this, in the present example embodiment, TCFa of the first resonator 1A serving as the series arm resonator is approximately 0 ppm/° C. Thus, even if the series arm resonator operates and rises in temperature, the anti-resonant frequency is less likely to become close to the pass band of the filter apparatus 1 defining and functioning as the band pass filter. Accordingly, even if the temperature rises, the insertion loss of the filter apparatus 1 is less likely to increase, which makes it possible to reduce or prevent deterioration of the filter characteristics of the filter apparatus 1.

The thickness of the first piezoelectric layer 5A is, for example, preferably about 0.05λ or more and about 0.5λ or less. With the thickness of the first piezoelectric layer 5A set to about 0.05λ or more, it is possible to reduce or prevent deterioration of the resonance characteristics of the first resonator 1A. With the thickness of the first piezoelectric layer 5A set to about 0.5λ or less, the insertion loss of the filter apparatus 1 is much less likely to increase.

Here, at least one of the first resonators 1A may be a series arm resonator. Also in this case, it is possible to reduce or prevent deterioration of the filter characteristics of the filter apparatus 1. Instead, for example, the filter apparatus 1 may be a multiplexer including at least one ladder filter. Then, the at least one ladder filter may include at least one first resonator 1A and at least one second resonator 1B. The at least one first resonator 1A included in the ladder filter may be a series arm resonator. Moreover, the ladder filter may include multiple first resonators 1A, and the multiple first resonators 1A may be series arm resonators. Also in these cases, it is possible to reduce or prevent deterioration of the filter characteristics of the ladder filter in the filter apparatus.

On the other hand, as shown in FIGS. 8 and 9, the pass band of the band pass filter is provided at the anti-resonant frequency of the parallel arm resonator. Meanwhile, the resonant frequency of the parallel arm resonator is a frequency lower than the pass band. However, if the resonant frequency is close to the pass band, the insertion loss of the band pass filter may be large. Here, when the parallel arm resonator operates, the temperature of the parallel arm resonator rises. If TCFr of the parallel arm resonator is a positive value, the resonant frequency of the parallel arm resonator becomes closer to the pass band of the band pass filter as the temperature rises.

In contrast to this, in the present example embodiment, TCFr of the second resonator 1B serving as the parallel arm resonator is close to 0 ppm/° C. Thus, even if the parallel arm resonator operates and rises in temperature, the resonant frequency is less likely to become close to the pass band of the filter apparatus 1 serving as the band pass filter. Accordingly, even if the temperature rises, the insertion loss of the filter apparatus 1 is less likely to increase, which makes it possible to reduce or prevent deterioration of the filter characteristics of the filter apparatus 1. Here, for example, the filter apparatus 1 may be a multiplexer including at least one ladder filter. Then, the at least one ladder filter may include at least one first resonator 1A and at least one second resonator 1B. The at least one second resonator 1B included in the ladder filter may be a parallel arm resonator. Moreover, the ladder filter may include multiple second resonators 1B, and the multiple second resonators 1B may be parallel arm resonators. Also in these cases, it is possible to reduce or prevent deterioration of the filter characteristics of the ladder filter in the filter apparatus. Even in these cases, at least one first resonator 1A included in the ladder filter may be a series arm resonator.

In the present example embodiment, both of the multiple first resonators 1A and the multiple second resonators 1B are surface acoustic wave resonators. However, at least one resonator among the multiple first resonators 1A and the multiple second resonators 1B may be configured to be capable of using, for example, bulk waves in a thickness shear mode as a main mode. In this case, for example, it is sufficient that this resonator is configured such that d/p is about 0.5 or less, where d denotes the thickness of the piezoelectric layer and p denotes the electrode finger pitch.

Instead, for example, at least one resonator among the multiple first resonators 1A and the multiple second resonators 1B may be a bulk acoustic wave (BAW) element. In this case, the functional electrodes of the resonator are a pair of excitation electrodes facing each other across the piezoelectric layer.

Hereinafter, examples of a material for each of members in example embodiments of the present invention will be described.

Examples of a material usable for the first piezoelectric layer 5A and the second piezoelectric layer 5B include lithium tantalate, lithium niobate, zinc oxide, aluminum nitride, scandium aluminum nitride, or the like. However, it is preferable to use rotated Y-cut lithium tantalate or lithium niobate as the material for the first piezoelectric layer 5A and the second piezoelectric layer 5B.

Examples of a material usable for the first intermediate layer 4A and the second intermediate layer 4B include dielectrics such as glass, silicon oxide, silicon oxynitride, lithium oxide, tantalum oxide, or compounds of silicon oxide with fluorine, carbon, or boron added, and materials containing the above materials as their main components. In the present description, the main component refers to a component which accounts for more than 50 wt %. The above materials as the main components may be, for example, in any of a single crystal state, a polycrystal state, an amorphous state, or a mixture of these states.

Examples of a material usable for the first supporting substrate 3A and the second supporting substrate 3B include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, semiconductors such as silicon or gallium arsenide, and materials including the above materials as their main components. The spinel includes, for example, an aluminum compound including oxygen and one or more elements selected from Mg, Fe, Zn, Mn, or the like. Examples of the spinel include MgAl₂O₄, FeAl₂O₄, ZnAl₂O₄, or MnAl₂O₄.

Examples of a material usable for the first IDT electrode 12A and the second IDT electrode 12B include Al, Cu, Pt, Ti, Mo, W, Ru, Au, Ag, or alloys including these materials as their main components. Also in the case where the first resonator 1A or the second resonator 1B is a BAW element, the same material as the first IDT electrode 12A and the second IDT electrode 12B may be used for the functional electrodes.

Here, the first resonator 1A may be, for example, a longitudinally coupled resonator acoustic wave resonator. A first resonator 1C in a first modification of the first example embodiment illustrated in FIG. 10 is, for example, a longitudinally coupled resonator acoustic wave resonator of a 5-IDT type. Specifically, the first resonator 1C includes five first IDT electrodes 12C, 12D, 12E, 12F, and 12G. However, the number of first IDT electrodes in the first resonator 1C is not limited to five. The first resonator 1C may be a longitudinally coupled resonator acoustic wave filter of any type such as a 3-IDT type, a 7-IDT type, or a 9-IDT type. Also in the present modification, it is possible to reduce or prevent deterioration of the reliability of the filter apparatus as in the first example embodiment.

FIG. 10 schematically illustrates wires in the first resonator 1C. The first resonator 1C is coupled to a wire coupled to a signal potential and a wire coupled to a ground potential. For example, an insulating film may be provided on the first piezoelectric layer 5A so as to cover a portion of the wire coupled to the signal potential or the wire coupled to the ground potential. Thus, a three-dimensional wiring section may be provided in which the wire coupled to the signal potential, the insulating film, and the wire coupled to the ground potential are stacked. This structure makes it possible to electrically insulate the above two types of wires from each other without increasing the area of the first piezoelectric layer 5A. Accordingly, the area of the filter apparatus can be kept from increasing.

Instead, at least one of the wire coupled to the signal potential and the wire coupled to the ground potential may be coupled to the electrode pad 7 not coupled to any of the through electrodes 9 illustrated in FIG. 1. Then, the above wire may be electrically coupled via the electrode pad 7 and the second support 6B to a wire provided on the second piezoelectric substrate 2B. In this case, even if no insulating film is provided, the two wires can be electrically insulated from each other.

Instead, the second resonator 1B may be a longitudinally coupled resonator acoustic wave filter, for example.

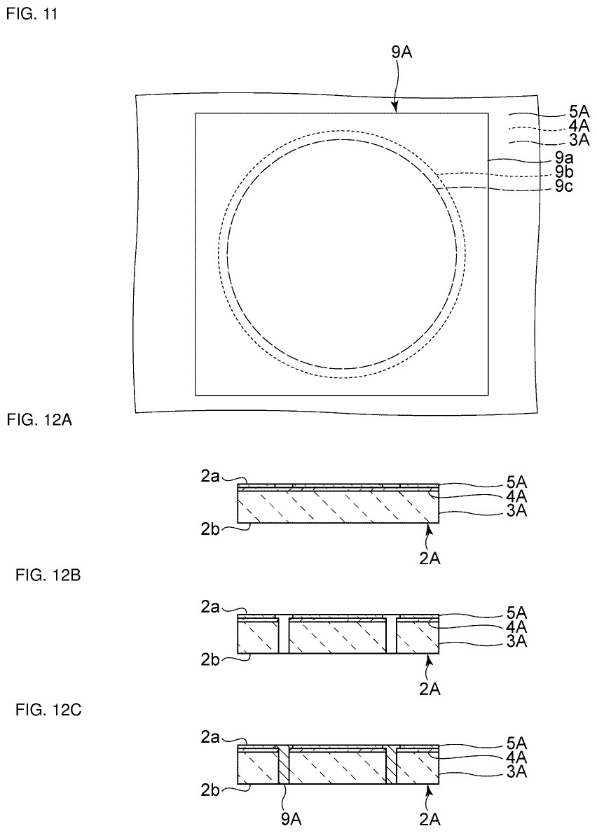

In the first example embodiment, the example is described in which the through holes are formed and the through electrodes 9 are provided in the first piezoelectric substrate 2A from the first supporting substrate 3A side. Instead, the through holes may be formed from the first piezoelectric layer 5A side after the first piezoelectric substrate 2A is prepared. In this case, as in a second modification of the first example embodiment illustrated in FIG. 11, the width of a portion of a through electrode 9A provided in the first piezoelectric layer 5A is wider than the width of a portion of the through electrode 9A provided in the first intermediate layer 4A. In plan view, a first outer circumferential edge 9a of the portion of the through electrode 9A provided in the first piezoelectric layer 5A is located outside a second outer circumferential edge 9b of the portion of the through electrode 9A provided in the first intermediate layer 4A.

Similarly, in plan view, the first outer circumferential edge 9a is located outside a third outer circumferential edge 9c of a portion of the through electrode 9A provided in the first supporting substrate 3A. This is because the through hole is formed in the first piezoelectric layer 5A first, and therefore the width of the through hole in the first piezoelectric layer 5A is wider than the widths of the through hole in the first intermediate layer 4A and the first supporting substrate 3A. In addition, the shape in plan view of the portion of the through electrode 9A provided in the first piezoelectric layer 5A may be different from the shape in plan view of the portion of the through electrode 9A provided in the first intermediate layer 4A or the first supporting substrate 3A.

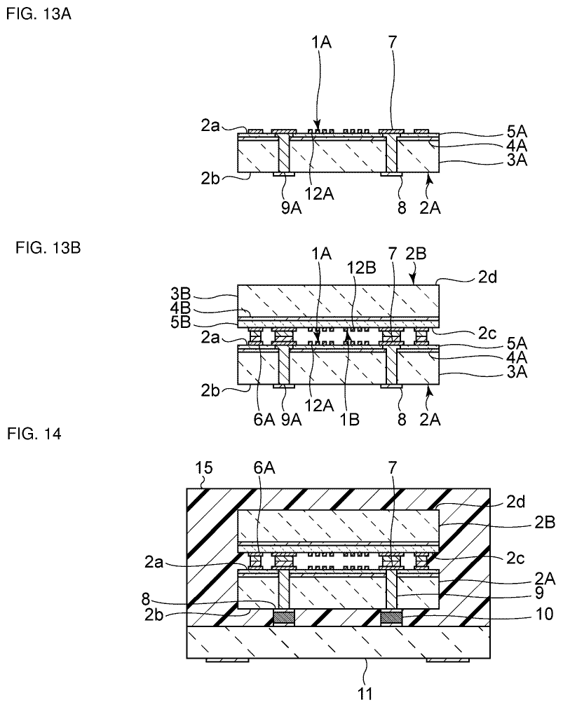

In order to obtain the filter apparatus in the present modification, more specifically, first, a first piezoelectric substrate 2A is prepared as illustrated in FIG. 12A. Next, through holes are formed in the first piezoelectric layer 5A. Subsequently, as illustrated in FIG. 12B, the through holes are formed in the first intermediate layer 4A and the first supporting substrate 3A so as to communicate with the through holes in the first piezoelectric layer 5A. Then, as illustrated in FIG. 12C, the through electrodes 9A are provided in the through holes. Next, as illustrated in FIG. 13A, the first IDT electrodes 12A, the electrode pads 7, and a partial layer of the first support 6A are formed on the first piezoelectric layer 5A. Next, the outer coupling terminals 8 are provided on the second main surface 2b of the first piezoelectric substrate 2A so as to be coupled to one end portions of the through electrodes 9A. After that, as illustrated in FIG. 13B, another partial layer of the first support 6A and the second supports 6B are provided to bond the first piezoelectric substrate 2A and the second piezoelectric substrate 2B together. Also in the step of forming the through holes in the first piezoelectric layer 5A for providing the through electrodes 9A in the present modification, the etching time can be shortened because the thickness of the first piezoelectric layer 5A is small. This can shorten the time for which the first supporting substrate 3A and others are etched, and reduce or prevent damages to the first supporting substrate 3A and others. For example, a crack is less likely to occur in the first supporting substrate 3A. Accordingly, it is possible to reduce or prevent deterioration of the reliability of the filter apparatus.

The filter apparatus according to example embodiments of the present invention may include a mounting substrate. For example, in a third modification of the first example embodiment illustrated in FIG. 14, a filter apparatus includes a mounting substrate 11, multiple bumps 10, and a sealing resin layer 15. A stack including the first piezoelectric substrate 2A and the second piezoelectric substrate 2B is mounted on the mounting substrate 11. Specifically, the outer coupling terminals 8 are bonded to the mounting substrate 11 with the respective bumps 10. The outer coupling terminals 8 may be bonded to the mounting substrate 11 with an appropriate conductive adhesive. The sealing resin layer 15 is provided on the mounting substrate 11 so as to entirely or substantially entirely cover the aforementioned stack.

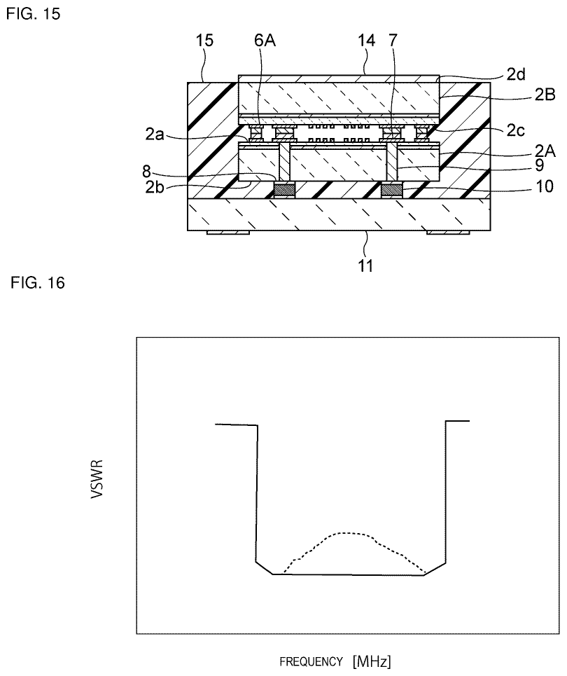

Instead, for example, in a fourth modification of the first example embodiment illustrated in FIG. 15, a sealing resin layer 15 covers the stack except for the fourth main surface 2d of the second piezoelectric substrate 2B. The fourth main surface 2d is not covered with the sealing resin layer 15. A shield electrode 14 is provided on the fourth main surface 2d. With this, it is possible to reduce or prevent electrical influence from outside.

Also in the third and fourth modifications, it is possible to reduce or prevent deterioration of the reliability of the filter apparatus as in the first example embodiment.

Hereinafter, structures in second to 12th example embodiments of the present invention will be described. Also in the second to 12th example embodiments, it is possible to reduce or prevent deterioration of the reliability of filter apparatuses as in the first example embodiment. The structure in the second example embodiment is the same or substantially the same as the structure in the first example embodiment except for a circuit structure. Thus, the second example embodiment will be described by referring to the drawings and the reference signs used in the first example embodiment.

The second example embodiment is different from the first example embodiment in that all of the first resonators 1A are parallel arm resonators. At the same time, in the second example embodiment, all of the parallel arm resonators of the filter apparatus are the first resonators 1A. The filter apparatus in the second example embodiment has the same or substantially the same structure as in the filter apparatus 1 in the first example embodiment except for the above point.

In the second example embodiment, even when the resonator operates and rises in temperature, deterioration of voltage standing wave ratio (VSWR) can be reduced or prevented. This advantageous effect will be described below in detail.

FIG. 16 is a schematic diagram of VSWR in the second example embodiment. In FIG. 16, VSWR in the second example embodiment is schematically shown by a solid line. An example in which VSWR in the background art deteriorates with a rise of temperature is shown by a broken line.

As schematically shown in FIG. 16, VSWR in the second example embodiment is less likely to deteriorate even when the temperature of the resonator rises. This is because the thickness of the first piezoelectric layer 5A in the first resonator 1A as the parallel arm resonator is small. In the second example embodiment, the thickness of the first piezoelectric layer 5A is small as in the first example embodiment. Therefore, in the first resonator 1A, TCFa can be made approximately 0 ppm/° C.

For example, as the anti-resonant frequency of the parallel arm resonator varies, VSWR may deteriorate. In contrast, in the second example embodiment, even when the temperature of the first resonator 1A as the parallel arm resonator rises, the anti-resonant frequency is less likely to vary. Therefore, VSWR is less likely to deteriorate.

In the second resonator 1B as a series arm resonator, the thickness of the second piezoelectric layer 5B is large. Therefore, in the second resonator 1B, TCFr can be made a value close to 0 ppm/° C.

For example, as the resonant frequency of the series arm resonator varies, VSWR may deteriorate. In contrast, in the second example embodiment, even when the temperature of the second resonator 1B as the series arm resonator rises, the resonant frequency is less likely to vary. Therefore, VSWR is less likely to deteriorate.

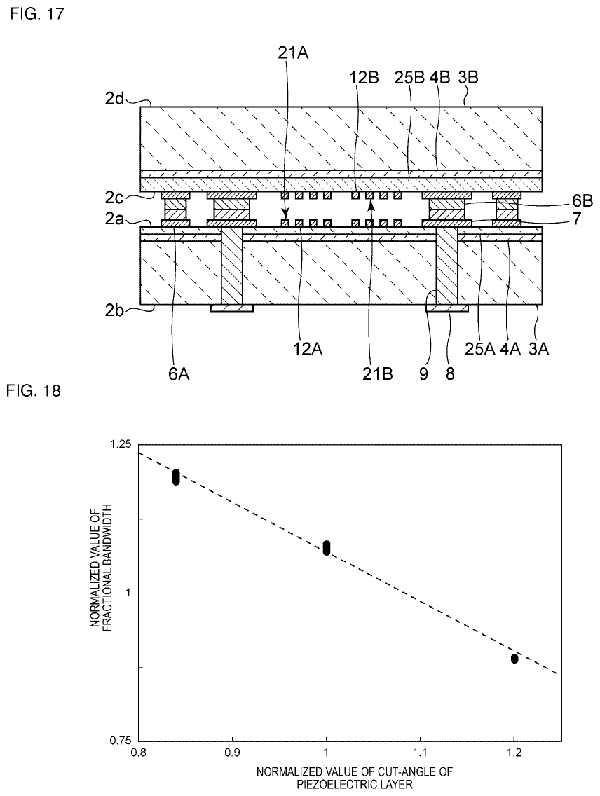

FIG. 17 is a schematic elevational sectional view of a filter apparatus according to a third example embodiment of the present invention.

In the present example embodiment, both of a first piezoelectric layer 25A and a second piezoelectric layer 25B are rotated Y-cut LiTaO₃ layers. The present example embodiment is different from the first example embodiment in that the cut-angle of the first piezoelectric layer 25A and the cut-angle of the second piezoelectric layer 25B are different from each other. The filter apparatus in the present example embodiment has the same or substantially the same structure as in the filter apparatus 1 in the first example embodiment except for the above points.

In the present description, the statement that “the cut-angle of a first piezoelectric layer and the cut-angle of a second piezoelectric layer are different from each other” means that the difference in cut-angle between these layers is about 0.5° or more.

In the present example embodiment, specifically, the cut-angle of the first piezoelectric layer 25A is, for example, about 55° Y. The cut-angle of the second piezoelectric layer 25B is, for example, about 35° Y. However, the cut-angles of the first piezoelectric layer 25A and the second piezoelectric layer 25B are not limited to the above. In the present example embodiment, steepness in the filter apparatus can be improved. In the present description, high steepness means that an amount of change in frequency is small for a certain amount of change in attenuation near an end portion of a pass band. The above advantageous effect will be described below in detail.

FIG. 18 is a diagram showing a relationship between the cut-angle of the piezoelectric layer and a fractional bandwidth in the resonator in the third example embodiment. Here, the fractional bandwidth is expressed by (|fa−fr|/fr)×100[%], where fr denotes a resonant frequency and fa denotes an anti-resonant frequency. In FIG. 18, the cut-angle and the fractional bandwidth are shown as normalized values.

As shown in FIG. 18, the larger the cut-angle of the piezoelectric layer, the smaller the value of the fractional bandwidth. The smaller the fractional bandwidth, the smaller the difference between the resonant frequency and the anti-resonant frequency. In the present example embodiment, the cut-angle of the first piezoelectric layer 25A is larger than the cut-angle of the second piezoelectric layer 25B. Accordingly, the value of the fractional bandwidth of a first resonator 21A is smaller than the value of the fractional bandwidth of a second resonator 21B.

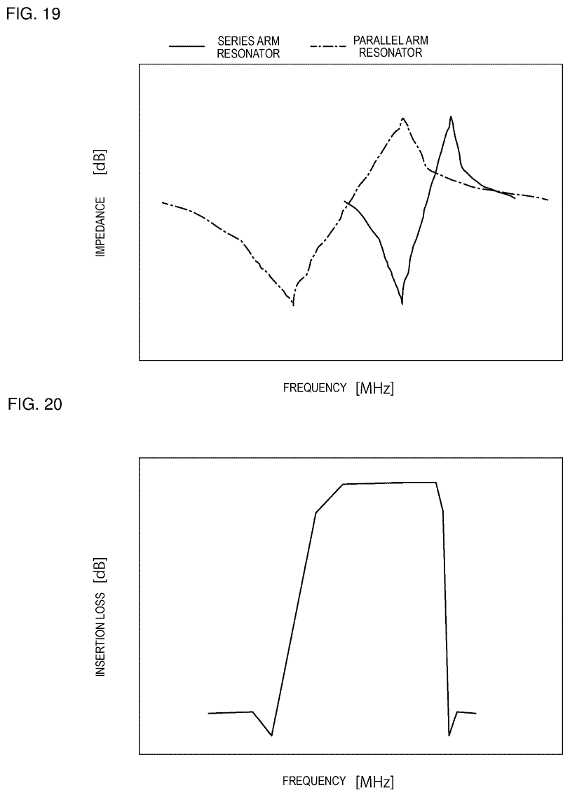

FIG. 19 is a schematic diagram of frequency characteristics of impedances of a series arm resonator and a parallel arm resonator in the third example embodiment. FIG. 20 is a schematic diagram of frequency characteristics of an attenuation of the filter apparatus in the third example embodiment.

In the present example embodiment, the first resonator 21A is a series arm resonator. Therefore, the fractional bandwidth of the first resonator 21A has a large influence on a high-frequency side of the pass band of the filter apparatus. As shown in FIG. 19, the value of the fractional bandwidth of the series arm resonator as the first resonator 21A is small. Accordingly, as shown in the FIG. 20, the steepness near the end portion on the high-frequency side of the pass band of the filter apparatus can be improved.

However, the first resonator 21A may be a parallel arm resonator. In this case, the fractional bandwidth of the first resonator 21A has a large influence on a low-frequency side of the pass band of the filter apparatus. Then, the value of the fractional bandwidth of the first resonator 21A is small. Accordingly, the steepness near the end portion on the low-frequency side of the pass band of the filter apparatus can be improved.

Hereinafter, a structure in a fourth example embodiment of the present invention will be described. The structure in the fourth example embodiment is the same or substantially the same as the structure in the first example embodiment except for materials for the piezoelectric layers. Thus, the fourth example embodiment will be described by referring to the drawings and the reference signs used in the first example embodiment.

The fourth example embodiment is different from the first example embodiment in that a material used for the first piezoelectric layer 5A and a material used for the second piezoelectric layer 5B are different from each other. The filter apparatus in the fourth example embodiment has the same or substantially the same structure as in the filter apparatus 1 in the first example embodiment except for the above point.

In the fourth example embodiment, the fractional bandwidths of the first resonator 1A and the second resonator 1B may be suitably adjusted as in the third example embodiment. Thus, the steepness in the filter apparatus can be improved.

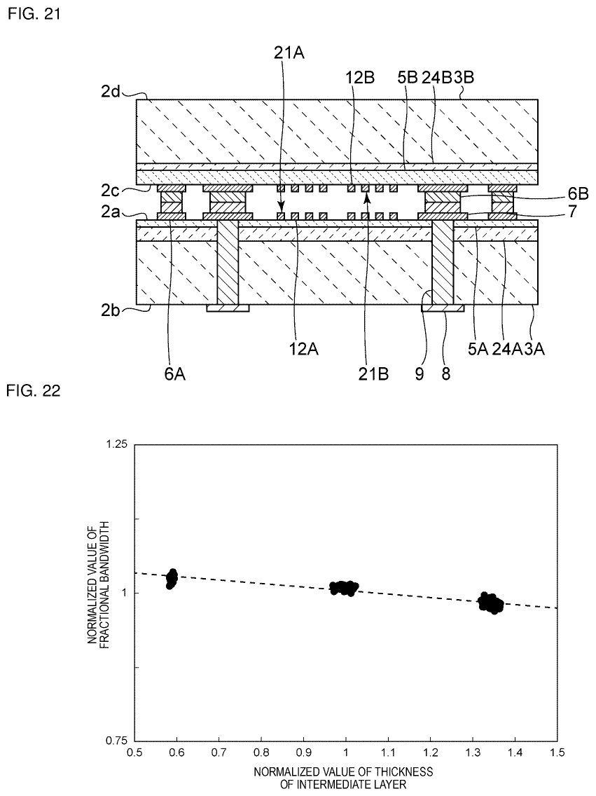

FIG. 21 is a schematic elevational sectional view of a filter apparatus according to a fifth example embodiment of the present invention.

The present example embodiment is different from the first example embodiment in that the thickness of a first intermediate layer 24A and the thickness of a second intermediate layer 24B are different from each other. The filter apparatus in the present example embodiment has the same or substantially the same structure as in the filter apparatus 1 in the first example embodiment except for the above point. In the present example embodiment, for example, silicon oxide is used as a material for the first intermediate layer 24A and the second intermediate layer 24B as in the first example embodiment.

In the present description, the statement that “the thickness of a first intermediate layer and the thickness of a second intermediate layer are different from each other” means that a difference in thickness between these layers is about 5% or more with respect to any of the thickness of the first intermediate layer and the thickness of the second intermediate layer.

In the present example embodiment, specifically, the thickness of the first intermediate layer 24A is, for example, about 600 nm. The thickness of the second intermediate layer 24B is, for example, about 300 nm. However, the thicknesses of the first intermediate layer 24A and the second intermediate layer 24B are not limited to the above. In the present example embodiment, the steepness of the filter apparatus can be improved as in the third example embodiment. The above advantageous effect will be described below in detail.

FIG. 22 is a diagram showing a relationship between the thickness of the intermediate layer and a fractional bandwidth in the resonator in the fifth example embodiment. In FIG. 22, the thickness of the intermediate layer and the fractional bandwidth are shown as normalized values.

As shown in FIG. 22, it is seen that the larger the thickness of the intermediate layer, the smaller the value of the fractional bandwidth. In the present example embodiment, the thickness of the first intermediate layer 24A is larger than the thickness of the second intermediate layer 24B. For this reason, the value of the fractional bandwidth of the first resonator 21A is smaller than the value of the fractional bandwidth of the second resonator 21B. Then, the first resonator 21A is a series arm resonator. Thus, as in the third example embodiment, the steepness near the end portion on the high-frequency side of the pass band of the filter apparatus can be improved.

Instead, the first resonator may be a parallel arm resonator. In this case, the steepness near the end portion on the low-frequency side of the pass band of the filter apparatus can be improved.

The thickness of the first intermediate layer 24A or the second intermediate layer 24B is, for example, preferably about 350 nm or more and about 500 nm or less, and more preferably about 400 nm or more and about 450 nm or less. Such thickness makes it possible to reduce or prevent harmonic waves as unwanted waves. The harmonic waves are harmonic waves occurring at approximately 1.5 times the main mode. This advantageous effect will be described below in detail.

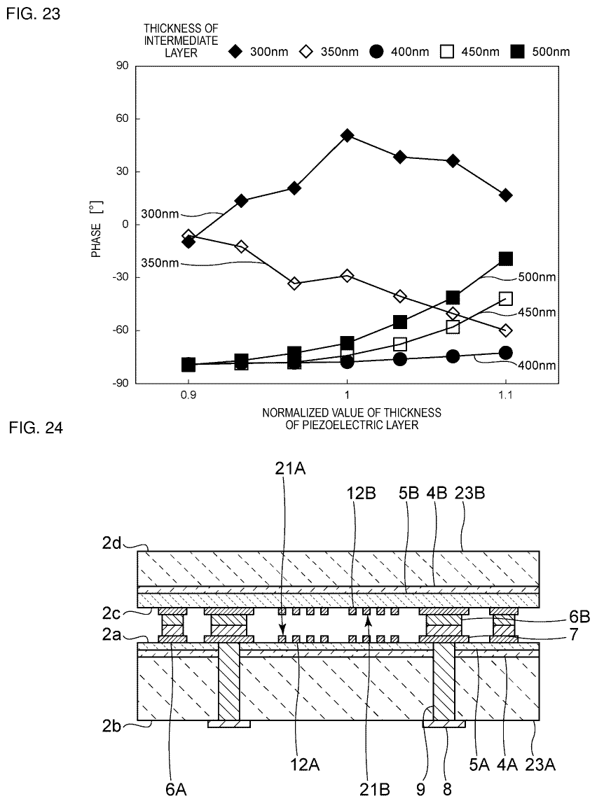

FIG. 23 is a diagram showing a relationship among the thickness of a piezoelectric layer, the thickness of an intermediate layer, and the phase of harmonic waves. In FIG. 23, the thickness of the piezoelectric layer is shown as a normalized value.

As shown in FIG. 23, it is seen that, in the case where the thickness of the intermediate layer is about 350 nm or more and about 500 nm or less, the phase of the harmonic waves is maintained lower than 0° regardless of the thickness of the piezoelectric layer. It is seen that the harmonic waves are further reduced or prevented in the case where the thickness of the intermediate layer is about 400 nm or more and about 450 nm or less.

The material for the first intermediate layer 24A and the material for the second intermediate layer 24B may be different from each other. In this case, it is possible to adjust a type of harmonic waves which are likely to occur. Therefore, it is possible to adjust the frequency of the main mode of each resonator, the frequency at which harmonic waves will occur, and the like. Thus, in an example where the filter apparatus is a multiplexer, the filter apparatus can be adjusted so that the frequency at which harmonic waves will occur is not located within the pass band of any of the band pass filters. In addition, as in the present example embodiment, it is also possible to reduce or prevent deterioration of the reliability of the filter apparatus.

FIG. 24 is a schematic elevational sectional view of a filter apparatus according to a sixth example embodiment of the present invention.

The present example embodiment is different from the first example embodiment in that the thickness of a first supporting substrate 23A and the thickness of a second supporting substrate 23B are different from each other. Specifically, the thickness of the first supporting substrate 23A is larger than the thickness of the second supporting substrate 23B. The filter apparatus in the present example embodiment has the same or substantially the same structure as in the filter apparatus 1 in the first example embodiment except for the above point.

In the present description, the statement that “the thickness of a first supporting substrate and the thickness of a second supporting substrate are different from each other” means that a difference in thickness between these substrates is about 50 nm or more.

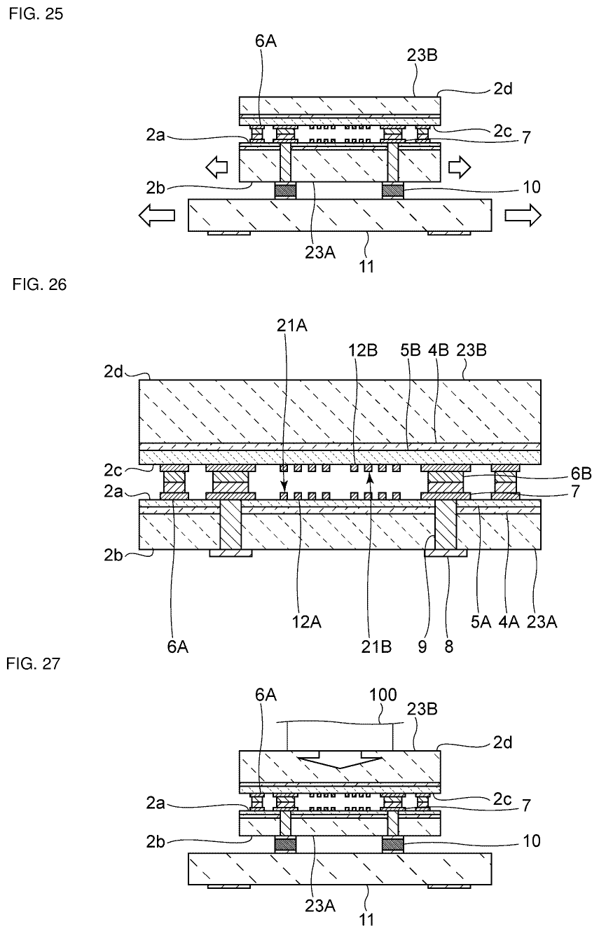

In the present example embodiment, a crack is less likely to occur in the first supporting substrate 23A in the process of mounting the stack including the first piezoelectric substrate and the second piezoelectric substrate on the mounting substrate. For example, as schematically illustrated by arrows in FIG. 25, in the process of mounting the stack on the mounting substrate 11, thermal stress is applied to the mounting substrate 11 and the first supporting substrate 23A. Also, even after the stack is mounted on the mounting substrate 11, thermal stress is applied to the mounting substrate 11 and the first supporting substrate 23A when the filter apparatus is in use. Also in these cases, the first supporting substrate 23A has a large thickness and therefore is less likely to be damaged. Thus, the reliability of the filter apparatus can be further improved.

FIG. 26 is a schematic elevational sectional view of a filter apparatus according to a seventh example embodiment of the present invention.

The present example embodiment is different from the first example embodiment in that the thickness of a second supporting substrate 23B is larger than the thickness of a first supporting substrate 23A. The filter apparatus in the present example embodiment has the same or substantially the same structure as in the filter apparatus 1 in the first example embodiment except for the above point.

In the present example embodiment, in the process of mounting the stack including the first piezoelectric substrate and the second piezoelectric substrate on the mounting substrate, a crack is less likely to occur in the second supporting substrate 23B. For example, as schematically illustrated in FIG. 27, in the process of mounting the stack on the mounting substrate 11, a suction collet 100 sucks the second supporting substrate 23B and transports the stack. After that, the stack is mounted on the mounting substrate 11. During mounting, a particularly large impact is applied to the second supporting substrate 23B. To address this, in the present example embodiment, the second supporting substrate 23B has a large thickness and therefore is less likely to be damaged. Thus, the reliability of the filter apparatus can be further improved.

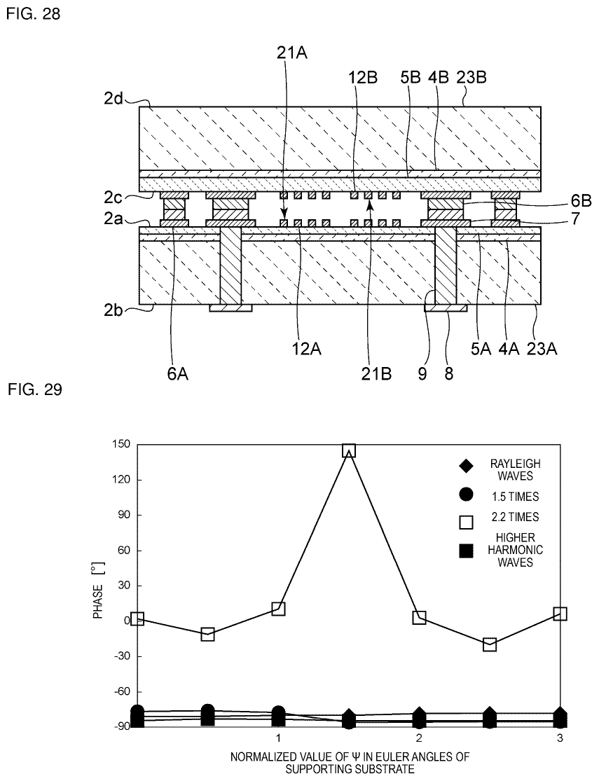

FIG. 28 is a schematic elevational sectional view of a filter apparatus according to an eighth example embodiment of the present invention.

The present example embodiment is different from the first example embodiment in that the crystal orientations of a first supporting substrate 23A and a second supporting substrate 23B are different from each other in terms of ψ in Euler angles (φ, θ, ψ). The filter apparatus in the present example embodiment has the same or substantially the same structure as in the filter apparatus 1 in the first example embodiment except for the above point. In the present example embodiment, for example, silicon is used as a material for the first supporting substrate 23A and the second supporting substrate 23B.

In the present description, the statement that “the first supporting substrate and the second supporting substrate are different from each other in terms of ψ in Euler angles (φ, θ, ψ)” means that a difference in ψ between these substrates is about 1° or more.

In the present example embodiment, it is possible to adjust a type of harmonic waves which are likely to occur. Therefore, it is possible to adjust the frequency of the main mode of each resonator, the frequency at which harmonic waves will occur, and the like. Thus, in a case where the filter apparatus is a multiplexer, the filter apparatus can be adjusted so that the frequency at which harmonic waves will occur is not located within the pass band of any of the band pass filters.

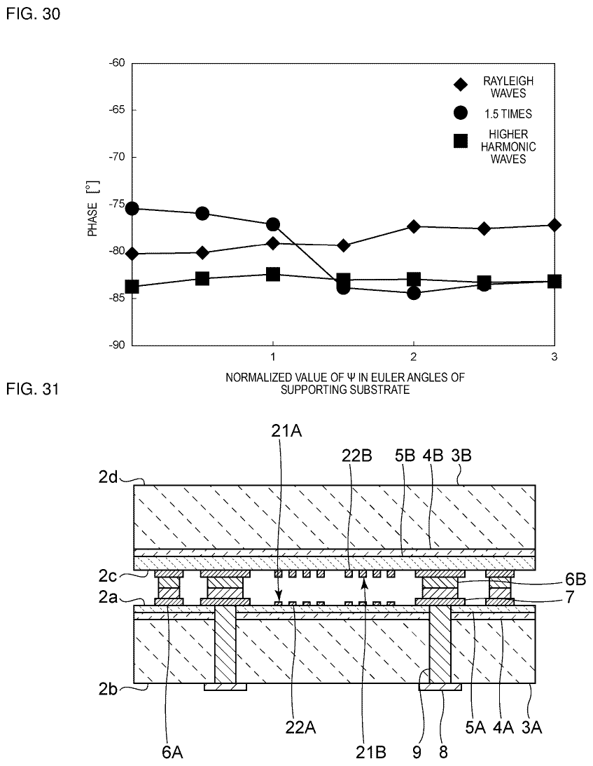

FIG. 29 is a diagram showing a relationship between ψ in Euler angles (φ, θ, ψ) of a supporting substrate and the phases of Rayleigh waves and harmonic waves. FIG. 30 is a diagram showing the relationship shown in FIG. 29 in the case where the phase is about −60° or less. In FIGS. 29 and 30, ψ is shown as a normalized value. In the following description, harmonic waves occurring at a frequency higher than about 2.2 times the main mode will be referred to as higher harmonic waves.

As shown in FIG. 29, the phase of harmonic waves occurring at a frequency around 2.2 times the frequency at which the main mode occurs is particularly highly dependent on ψ in Euler angles (φ, θ, ψ) of the supporting substrate. However, as shown in FIG. 30, it is seen that the phases of harmonic waves occurring at a frequency around 1.5 times the frequency of the main mode, the higher harmonic waves, and the Rayleigh waves are also dependent on ψ in Euler angles (φ, θ, ψ) of the supporting substrate.

Hereinafter, a structure according to a ninth example embodiment of the present invention will be described. The structure in the ninth example embodiment is the same or substantially the same as the structure in the first example embodiment except for materials for the supporting substrates. Thus, the ninth example embodiment will be described by referring to the drawings and the reference signs used in the first example embodiment.

The ninth example embodiment is different from the first example embodiment in that the material used for the first supporting substrate 3A and the material used for the second supporting substrate 3B are different from each other. The filter apparatus in the ninth example embodiment has the same or substantially the same structure as in the filter apparatus 1 in the first example embodiment except for the above point.

In the structure in the ninth example embodiment, for example, a temperature coefficient of frequency (TCF) of each of the first supporting substrate 3A and the second supporting substrate 3B can be adjusted. Accordingly, TCF of the first resonator 1A provided on the first piezoelectric substrate 2A and TCF of the second resonator 1B provided on the second piezoelectric substrate 2B can be adjusted. Therefore, in each resonator, for example, TCFr or TCFa can be made close to 0. As a result, it is possible to obtain an advantageous effect of improving the steepness, an advantageous effect of reducing or preventing deterioration of VSWR, and so on.

It is preferable that the heat dissipation of the material used for the first supporting substrate 3A is higher than the heat dissipation of the material used for the second supporting substrate 3B. This makes it possible to improve the electric power handling capability of the filter apparatus.

Use of a material with high strength for the first supporting substrate 3A makes it possible to make a crack less likely to occur in the first supporting substrate 3A as in the sixth example embodiment. Therefore, the reliability of the filter apparatus can be further improved. Here, as a material for the second supporting substrate 3B, for example, a material for adjusting TCFr or TCFa, a material capable of reducing or preventing harmonic waves, or the like may be used.

Instead, use of a material with high strength for the second supporting substrate 3B makes it possible to make a crack less likely to occur in the second supporting substrate 3B as in the seventh example embodiment. Therefore, the reliability of the filter apparatus can be further improved. Here, as a material for the second supporting substrate 3B, for example, a material for adjusting TCFr or TCFa, a material capable of reducing or preventing harmonic waves, a material having high heat dissipation, or the like may be used.

FIG. 31 is a schematic elevational sectional view of a filter apparatus according to a tenth example embodiment of the present invention.

The present example embodiment is different from the first example embodiment in that the thickness of a first IDT electrode 22A and the thickness of a second IDT electrode 22B are different from each other. Specifically, the thickness of the first IDT electrode 22A is smaller than the thickness of the second IDT electrode 22B. The filter apparatus in the present example embodiment has the same or substantially the same structure as in the filter apparatus 1 in the first example embodiment except for the above point. Here, in the present example embodiment, for example, Al is used as a material for the first IDT electrode 22A and the second IDT electrode 22B.

In the present description, the statement that “the thickness of a first IDT electrode and the thickness of a second IDT electrode are different from each other” means that the difference in thickness between these electrodes is about 5% or more with respect to any of the thickness of the first IDT electrode and the thickness of the second IDT electrode.

The thickness of the first IDT electrode 22A is, for example, about 0.05λ. The thickness of the second IDT electrode 22B is, for example, about 0.1λ. However, the thicknesses of the first IDT electrode 22A and the second IDT electrode 22B are not limited to the above.

In the present example embodiment, as in the first example embodiment, even if the temperature rises, the insertion loss of the filter apparatus is less likely to increase, which makes it possible to reduce or prevent deterioration of the filter characteristics of the filter apparatus. This advantageous effect will be described below in detail.

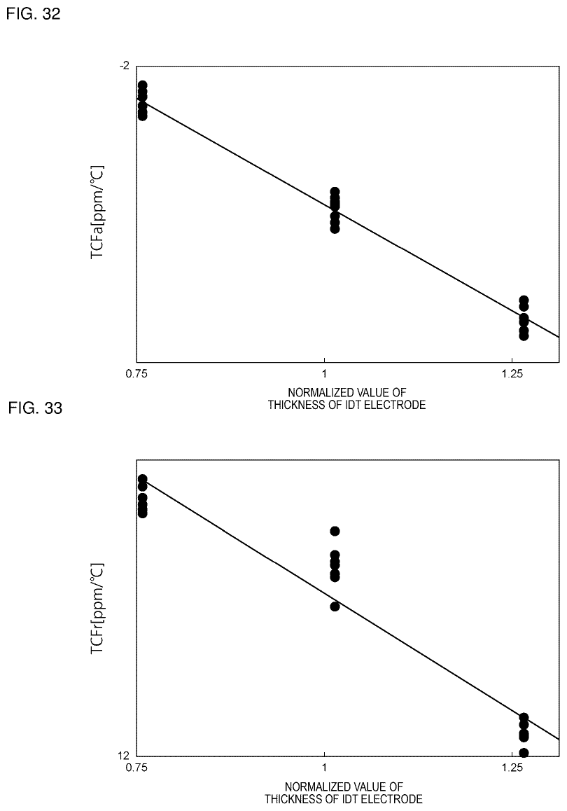

FIG. 32 is a diagram showing a relationship between the thickness of an IDT electrode and TCFa. FIG. 32 shows an example in which Al is used as a material for the IDT electrode. In FIG. 32, the thickness of the IDT electrode is shown as a normalized value.

As shown in FIG. 32, the larger the thickness of the IDT electrode, the larger TCFa becomes in the negative direction. Here, the first resonator 21A is a series arm resonator. Then, in the first resonator 21A, the thickness of the first IDT electrode 22A is small. Therefore, in the first resonator 21A defining and functioning as the series arm resonator, TCFa can be made close to 0 ppm/° C. Thus, even if the temperature of the first resonator 21A rises, the anti-resonant frequency of the first resonator 21A is less likely to become close to the pass band in the filter apparatus.

FIG. 33 is a diagram showing a relationship between the thickness of an IDT electrode and TCFr. FIG. 33 shows an example in which Al is used as a material for the IDT electrode. In FIG. 33, the thickness of the IDT electrode is shown as a normalized value.

As shown in FIG. 33, the larger the thickness of the IDT electrode, the larger TCFr becomes in the negative direction. Here, the second resonator 21B is a parallel arm resonator. Then, in the second resonator 21B, the thickness of the second IDT electrode 22B is large. Therefore, in the second resonator 21B defining and functioning as the parallel arm resonator, TCFr can be made close to 0 ppm/° C. Thus, even if the temperature of the second resonator 21B rises, the resonant frequency of the second resonator 21B is less likely to become close to the pass band in the filter apparatus. Thus, even if the temperature rises, the insertion loss of the filter apparatus is less likely to increase, which makes it possible to reduce or prevent deterioration of the filter characteristics of the filter apparatus.

As in the second example embodiment, the first resonator 21A may be a parallel arm resonator. In this case, it is preferable that the thickness of the first IDT electrode 22A be larger than the thickness of the second IDT electrode 22B. This makes it possible to reduce or prevent deterioration of VSWR.

It is preferable that the thicknesses of the first IDT electrode 22A and the second IDT electrode 22B is, for example, about 0.03λ or more and about 0.3λ or less. With the thicknesses of the first IDT electrode 22A and the second IDT electrode 22B set to about 0.03λ or more, the insertion loss of the filter apparatus is further less likely to increase. With the thicknesses of the first IDT electrode 22A and the second IDT electrode 22B set to about 0.3λ or less, it is possible to reduce or prevent deterioration of the electric power handling capability.

Hereinafter, a structure according to an 11th example embodiment of the present invention will be described. The structure in the 11th example embodiment is the same or substantially the same as the structure in the first example embodiment except for materials for the IDT electrodes. Thus, the 11th example embodiment will be described by referring to the drawings and the reference signs used in the first example embodiment.

The 11th example embodiment is different from the first example embodiment in that the material used for the first IDT electrode 12A and the material used for the second IDT electrode 12B are different from each other. The filter apparatus in the 11th example embodiment has the same or substantially the same structure as in the filter apparatus 1 in the first example embodiment except for the above point.

In the present example embodiment, as in the first example embodiment, the first resonator 1A is a series arm resonator. The second resonator 1B is a parallel arm resonator. In this case, it is preferable that the electrical resistance of the material used for the second IDT electrode 12B is higher than the electrical resistance of the material used for the first IDT electrode 12A. Even if the electrical resistance is high in the parallel arm resonator, the filter characteristics in the filter apparatus 1 are less likely to deteriorate. In addition, the electric power handling capability of the parallel arm resonator can be improved.

Alternatively, it is preferable that the strength of the material used for the second IDT electrode 12B is higher than the strength of the material used for the first IDT electrode 12A. This makes it possible to improve the electric power handling capability of the parallel arm resonator.

Here, the first resonator 1A may be a parallel arm resonator, and the second resonator 1B may be a series arm resonator. In this case, it is preferable that the electrical resistance of the material used for the first IDT electrode 12A is higher than the electrical resistance of the material used for the second IDT electrode 12B. Alternatively, it is preferable that the strength of the material used for the first IDT electrode 12A is higher than the strength of the material used for the second IDT electrode 12B.

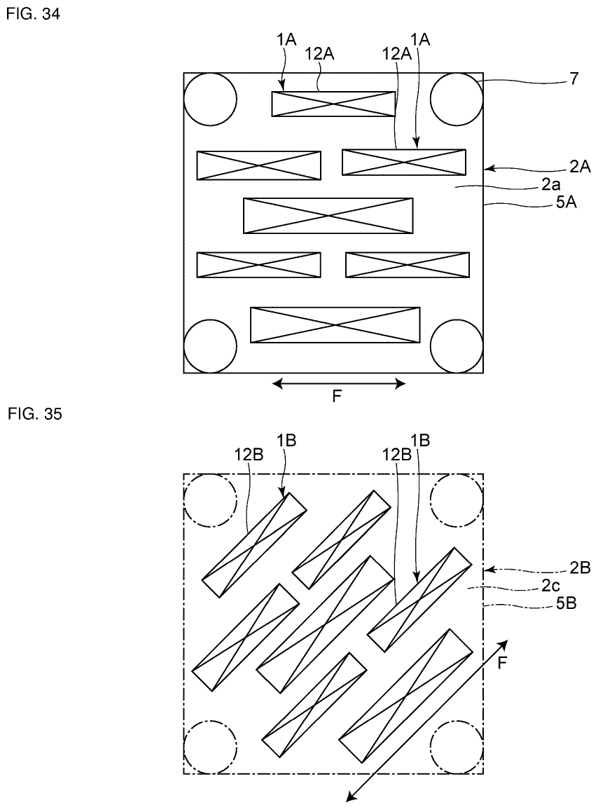

FIG. 34 is a schematic plan view illustrating a layout of resonators on a first main surface of a first piezoelectric substrate according to a 12th example embodiment of the present invention. FIG. 35 is a schematic see-through plan view illustrating a layout of resonators on a third main surface of a second piezoelectric substrate in the 12th example embodiment. In FIGS. 34 and 35, each resonator is illustrated as a schematic figure including a rectangular with two diagonal lines added. In FIGS. 34 and 35, a bidirectional arrow F indicates the acoustic wave propagation direction.

As illustrated in FIGS. 34 and 35, in the present example embodiment, in plan view, the present example embodiment is different from the first example embodiment in that the acoustic wave propagation direction in the first IDT electrodes 12A intersects the acoustic wave propagation direction in the second IDT electrodes 12B. The acoustic wave propagation direction is orthogonal or substantially orthogonal to the electrode finger extension direction. Thus, in plan view, the electrode finger extension direction of the first IDT electrodes 12A intersects the electrode finger extension direction of the second IDT electrodes 12B. The filter apparatus in the present example embodiment has the same or substantially the same structure as in the filter apparatus 1 in the first example embodiment except for the above point. In the present example embodiment, the first piezoelectric layer 5A and the second piezoelectric layer 5B have the same Euler angles (φ, θ, ψ).

The first resonator 1A and the second resonator 1B are different from each other in terms of the relationship between the acoustic wave propagation direction and Euler angles (φ, θ, ψ) of the piezoelectric layer. Thus, the fractional bandwidths of the first resonator 1A and the second resonator 1B can be differentiated from each other. In the present example embodiment, the first resonator 1A is a series arm resonator. Thus, with the fractional bandwidth of the first resonator 1A set to a small value, the steepness near the end portion on the high-frequency side of the pass band of the filter apparatus can be improved.

Instead, the first resonator 1A may be a parallel arm resonator. In this case, with the fractional bandwidth of the first resonator 1A set to a small value, the steepness near the end portion on the low-frequency side of the pass band of the filter apparatus can be improved.

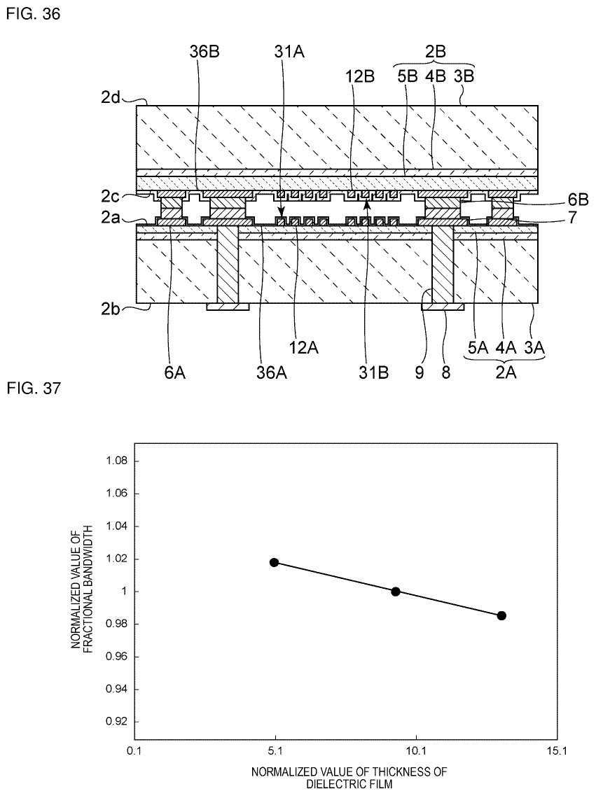

FIG. 36 is a schematic elevational sectional view of a filter apparatus according to a 13th example embodiment of the present invention.

The present example embodiment is different from the first example embodiment in that a first dielectric film 36A is provided on the first piezoelectric layer 5A so as to cover multiple first IDT electrodes 12A. The present example embodiment is different from the first example embodiment also in that a second dielectric film 36B is provided on the second piezoelectric layer 5B so as to cover multiple second IDT electrodes 12B. The filter apparatus in the present example embodiment has the same or substantially the same structure as in the filter apparatus 1 in the first example embodiment except for the above points.

Also in the present example embodiment, the through electrodes 9 are provided in the first piezoelectric substrate 2A and the thickness of the first piezoelectric layer 5A of the first piezoelectric substrate 2A is smaller than the thickness of the second piezoelectric layer 5B of the second piezoelectric substrate 2B as in the first example embodiment. This structure makes it possible to reduce or prevent deterioration of the reliability of the filter apparatus.

In addition, the multiple first IDT electrodes 12A are covered with the first dielectric film 36A. The multiple second IDT electrodes 12B are covered with the second dielectric film 36B. Thus, the IDT electrodes are protected by these films and therefore are less likely to be damaged.

In the present example embodiment, the thickness of the first dielectric film 36A and the thickness of the second dielectric film 36B are different from each other. Specifically, the thickness of the first dielectric film 36A is smaller than the thickness of the second dielectric film 36B. More specifically, the thickness of the first dielectric film 36A is, for example, about 0.015λ. The thickness of the second dielectric film 36B is, for example, about 0.025λ.

More specifically, the thickness of the first dielectric film 36A is a distance from a surface of the first dielectric film 36A in contact with the first IDT electrodes 12A to a surface of the first dielectric film 36A. Similarly, the thickness of the second dielectric film 36B is a distance from a surface of the second dielectric film 36B in contact with the second IDT electrodes 12B to a surface of the second dielectric film 36B. The wavelength λ, which is used as a basis for the thicknesses of the first dielectric film 36A and the second dielectric film 36B, is the shortest wavelength λ among wavelengths λ of all the first IDT electrodes 12A and all the second IDT electrodes 12B. However, the thicknesses of the first dielectric film 36A and the second dielectric film 36B are not limited to the above.

In the present description, the statement that “the thickness of one of the dielectric films and the thickness of the other dielectric film are different from each other” means that the difference in thickness between the two films is about ±5% or less. The statement that “the difference in thickness between the two films is about ±5% or less” specifically means that the absolute value of the difference in thickness between one of the dielectric films and the other dielectric film is about 5% or less with respect to any of the thicknesses of the two dielectric films.

Silicon oxide, for example, is used as the material for the first dielectric film 36A and the second dielectric film 36B. However, the material for the first dielectric film 36A and the second dielectric film 36B is not limited to the above. For example, a dielectric such as glass, silicon oxide, silicon oxynitride, lithium oxide, tantalum oxide, a compound of silicon oxide with fluorine, carbon, or boron added, or any of materials including the above materials as their main components may be used.

In the present example embodiment, the steepness of the pass band of the filter apparatus can be improved. This advantageous effect will be described below in detail. In the following description, the first dielectric film 36A and the second dielectric film 36B are collectively simply referred to as a dielectric film in some cases.

FIG. 37 is a diagram showing a relationship between the thickness of the dielectric film and the fractional bandwidth. In FIG. 37, the thickness of the dielectric film and the fractional bandwidth are shown as normalized values.

As shown in FIG. 37, the larger the thickness of the dielectric film, the smaller the value of the fractional bandwidth. In the present example embodiment, a second resonator 31B is a parallel arm resonator as in the first example embodiment. The thickness of the second dielectric film 36B is large. Therefore, in the second resonator 31B serving as the parallel arm resonator, the value of the fractional bandwidth can be made small. Accordingly, the steepness near the end portion on the low-frequency side of the pass band of the filter apparatus can be improved.

However, the thickness of the first dielectric film 36A may be larger than the thickness of the second dielectric film 36B. A first resonator 31A is a series arm resonator. Thus, in the first resonator 31A defining and functioning as the series arm resonator, the value of the fractional bandwidth can be made small. Accordingly, the steepness near the end portion on the high-frequency side of the pass band of the filter apparatus can be improved.

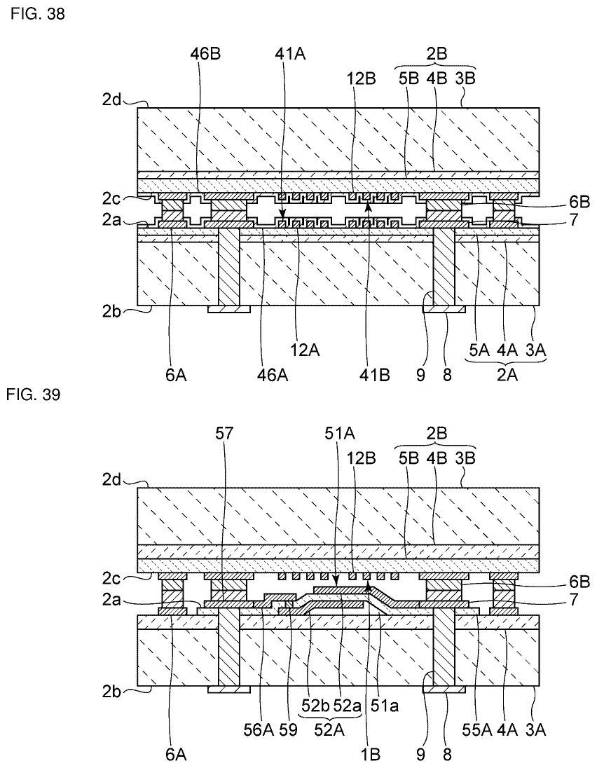

FIG. 38 is a schematic elevational sectional view of a filter apparatus according to a 14th example embodiment of the present invention.

The present example embodiment is different from the 13th example embodiment in that a first dielectric film 46A and a second dielectric film 46B has the same or substantially the same thickness. The present example embodiment is different from the 13th example embodiment also in that a material used for the first dielectric film 46A and a material used for the second dielectric film 46B are different from each other. The filter apparatus in the present example embodiment has the same or substantially the same structure as in the filter apparatus in the 13th example embodiment except for the above points.

Also in the present example embodiment, the through electrodes 9 are provided in the first piezoelectric substrate 2A and the thickness of the first piezoelectric layer 5A of the first piezoelectric substrate 2A is smaller than the thickness of the second piezoelectric layer 5B of the second piezoelectric substrate 2B as in the 13th example embodiment. This structure makes it possible to reduce or prevent deterioration of the reliability of the filter apparatus.

In addition, for example, the fractional bandwidths of a first resonator 41A and a second resonator 41B can be adjusted by a material used for the first dielectric film 46A and a material used for the second dielectric film 46B. Thus, as in the 13th example embodiment, the steepness of the pass band of the filter apparatus can be improved.

As described above, at least one resonator among the multiple first resonators and the multiple second resonators may be a BAW element, for example. Examples of this case will be described in 15th to 19th example embodiments of the present invention. In the 15th to 19th example embodiments, as in the first example embodiment, the through electrodes are provided in the first piezoelectric substrate and the thickness of the first piezoelectric layer in the first piezoelectric substrate is smaller than the thickness of the second piezoelectric layer in the second piezoelectric substrate. This structure makes it possible to reduce or prevent deterioration of the reliability of the filter apparatus in the 15th to 19th example embodiments.

FIG. 39 is a schematic elevational sectional view of an acoustic wave device according to the 15th example embodiment of the present invention.

The present example embodiment is different from the first example embodiment in that a first piezoelectric layer 55A has a different structure and multiple first resonators include a first resonator 51A defining and functioning as a BAW element. The present example embodiment is different from the first example embodiment also in that the first piezoelectric layer 55A is located inside the first support 6A in plan view. Furthermore, the present example embodiment is different from the first example embodiment in the structure of electrodes. The filter apparatus in the present example embodiment has the same or substantially the same structure as in the filter apparatus 1 in the first example embodiment except for the above points.

The first piezoelectric layer 55A includes a portion curved in a shape protruding toward the second piezoelectric substrate 2B. In a first piezoelectric substrate, a hollow portion 51a is provided, which is surrounded by the above portion of the first piezoelectric layer 55A and the first intermediate layer 4A.

A first functional electrode 52A of the first resonator 51A includes a first excitation electrode 52a and a second excitation electrode 52b. The first excitation electrode 52a and the second excitation electrode 52b face each other across the first piezoelectric layer 55A. The first excitation electrode 52a is provided on a main surface of the first piezoelectric layer 55A on the second piezoelectric substrate 2B side. In other words, the first excitation electrode 52a in the first functional electrode 52A is provided on the first main surface 2a of the first piezoelectric substrate.

An extended wire extends from the first excitation electrode 52a. In the present example embodiment, the first excitation electrode 52a and the extended wire are integrally made of the same material. The extended wire is coupled to the electrode pad 7 provided on the first piezoelectric layer 55A. Instead, the first excitation electrode 52a and the extended wire may be separately made of materials different from each other. The extended wire may electrically couple the first excitation electrode 52a and the electrode pad 7.

On the other hand, the second excitation electrode 52b is provided on a main surface of the first piezoelectric layer 55A on the first supporting substrate 3A side. The second excitation electrode 52b is provided inside the hollow portion 51a. An extended wire extends from the second excitation electrode 52b. In the present example embodiment, the second excitation electrode 52b and the extended wire are integrally made of the same material. Instead, the second excitation electrode 52b and the extended wire may be separately made of materials different from each other. The extended wire and the second excitation electrode 52b may be coupled to each other.

A through electrode 59 other than the through electrodes 9 is provided so as to pass through the first piezoelectric layer 55A. Specifically, in the present example embodiment, the through electrode 59 passes through only the first piezoelectric layer 55A among the multiple layers in the first piezoelectric substrate. The extended wire extending from the second excitation electrode 52b is coupled to the through electrode 59. A wire 56A is provided on the main surface of the first piezoelectric layer 55A on the second piezoelectric substrate 2B side. The wire 56A electrically couples an electrode pad 57 provided on the first piezoelectric layer 55A and the through electrode 59. This electrode pad 57 is an electrode pad different from the electrode pad 7 to which the first excitation electrode 52a is electrically coupled.

The first excitation electrode 52a is electrically coupled to outside via the extended wire, the electrode pad 7, the through electrode 9, and the outer coupling terminal 8. The second excitation electrode 52b is electrically coupled to outside via the extended wire, the through electrode 59, the wire 56A, the electrode pad 57, the through electrode 9, and the outer coupling terminal 8.

The first excitation electrode 52a and the second excitation electrode 52b are coupled to potentials different from each other. When an AC voltage is applied to the first excitation electrode 52a and the second excitation electrode 52b, bulk waves are excited.

In the present example embodiment, the first piezoelectric layer 55A is located inside the first support 6A in plan view. The first support 6A is provided on the first intermediate layer 4A in the first piezoelectric substrate. Instead, the first support 6A may be provided on the first piezoelectric layer 55A.

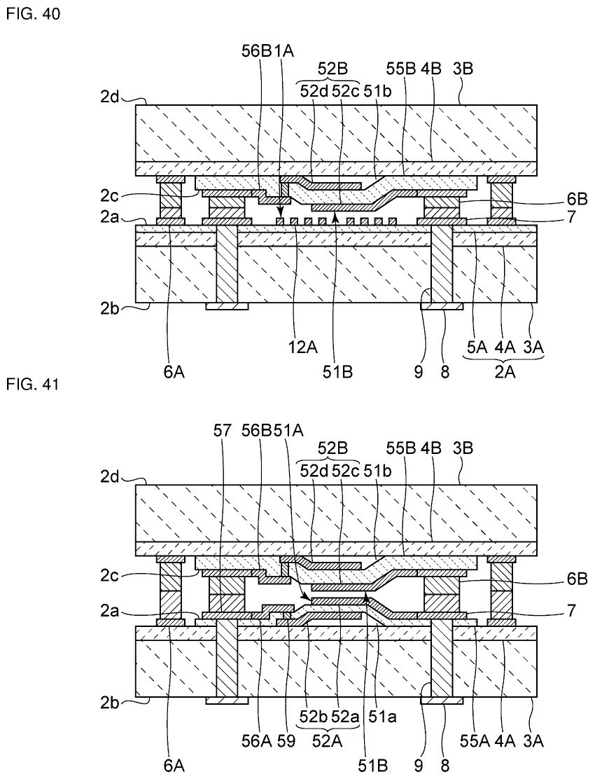

FIG. 40 is a schematic elevational sectional view of an acoustic wave device according to the 16th example embodiment of the present invention.

The present example embodiment is different from the first example embodiment in that a second piezoelectric layer 55B has a different structure and multiple second resonators include a second resonator 51B defining and functioning as a BAW element. The present example embodiment is different from the first example embodiment also in that the second piezoelectric layer 55B is located inside the first support 6A in plan view. Furthermore, the present example embodiment is different from the first example embodiment in the structure of electrodes. The filter apparatus in the present example embodiment has the same or substantially the same structure as in the filter apparatus 1 in the first example embodiment except for the above points.

The second piezoelectric layer 55B includes a portion curved in a shape protruding toward the first piezoelectric substrate 2A. In a second piezoelectric substrate, a hollow portion 51b is provided which is surrounded by the above portion of the second piezoelectric layer 55B and the second intermediate layer 4B.

A second functional electrode 52B of the second resonator 51B includes a first excitation electrode 52c and a second excitation electrode 52d. The first excitation electrode 52c and the second excitation electrode 52d face each other across the second piezoelectric layer 55B. The first excitation electrode 52c is provided on a main surface of the second piezoelectric layer 55B on the first piezoelectric substrate 2A side. In other words, the first excitation electrode 52c in the second functional electrode 52B is provided on the third main surface 2c of the second piezoelectric substrate.

An extended wire extends from the first excitation electrode 52c. In the present example embodiment, the first excitation electrode 52c and the extended wire are integrally made of the same material. The extended wire is coupled to an electrode pad provided on the second piezoelectric layer 55B. Instead, the first excitation electrode 52c and the extended wire may be separately made of materials different from each other. The extended wire may electrically couple the first excitation electrode 52c and the electrode pad.

On the other hand, the second excitation electrode 52d is provided on a main surface of the second piezoelectric layer 55B on the second supporting substrate 3B side. The second excitation electrode 52d is provided inside the hollow portion 51b. An extended wire extends from the second excitation electrode 52d. In the present example embodiment, the second excitation electrode 52d and the extended wire are integrally made of the same material. Instead, the second excitation electrode 52d and the extended wire may be separately made of materials different from each other. The extended wire and the second excitation electrode 52d may be coupled to each other.

A through electrode is provided so as to pass through the second piezoelectric layer 55B. Specifically, in the present example embodiment, the through electrode passes through only the second piezoelectric layer 55B among the multiple layers in the second piezoelectric substrate. The extended wire extending from the second excitation electrode 52d is coupled to this through electrode. A wire 56B is provided on the main surface of the second piezoelectric layer 55B on the first piezoelectric substrate 2A side. The wire 56B electrically couples an electrode pad provided on the second piezoelectric layer 55B and the through electrode. This electrode pad is an electrode pad different from the electrode pad to which the first excitation electrode 52c is electrically coupled. A second support 6B is provided on this electrode pad.

A second support 6B is provided on the electrode pad to which the first excitation electrode 52c is electrically coupled. The different second support 6B is provided also on the electrode pad to which the second excitation electrode 52d is electrically coupled. These second supports 6B are electrically coupled to the respective through electrodes 9 different from each other.

The first excitation electrode 52c is electrically coupled to outside via the extended wire, the electrode pad, the second support 6B, the through electrode 9, and the outer coupling terminal 8. The second excitation electrode 52d is electrically coupled to outside via the extended wire, the through electrode, the wire 56B, the electrode pad, the second support 6B, the through electrode 9, and the outer coupling terminal 8.

In the present example embodiment, the second piezoelectric layer 55B is located inside the first support 6A in plan view. The first support 6A is provided on the second intermediate layer 4B in the second piezoelectric substrate. Instead, the first support 6A may be provided on the second piezoelectric layer 55B.

FIG. 41 is a schematic elevational sectional view of an acoustic wave device according to the 17th example embodiment of the present invention.

The present example embodiment is different from the 15th example embodiment in that the second piezoelectric layer 55B has a different structure and multiple second resonators include a second resonator 51B serving as a BAW element. The present example embodiment is different from the 15th example embodiment also in that the second piezoelectric layer 55B is located inside the first support 6A in plan view. Furthermore, the present example embodiment is different from the 15th example embodiment in the structure of electrodes provided to the second piezoelectric substrate. The filter apparatus in the present example embodiment has the same or substantially the same structure as in the filter apparatus in the 15th example embodiment except for the above points.

Specifically, in the filter apparatus in the present example embodiment, the multiple first resonators include the first resonator 51A defining and functioning as the BAW element, and the multiple second resonators include the second resonator 51B defining and functioning as the BAW element. The structure of the electrodes provided to the second piezoelectric substrate in the present example embodiment is the same or substantially the same as the structure of the electrodes provided to the second piezoelectric substrate in the 16th example embodiment.

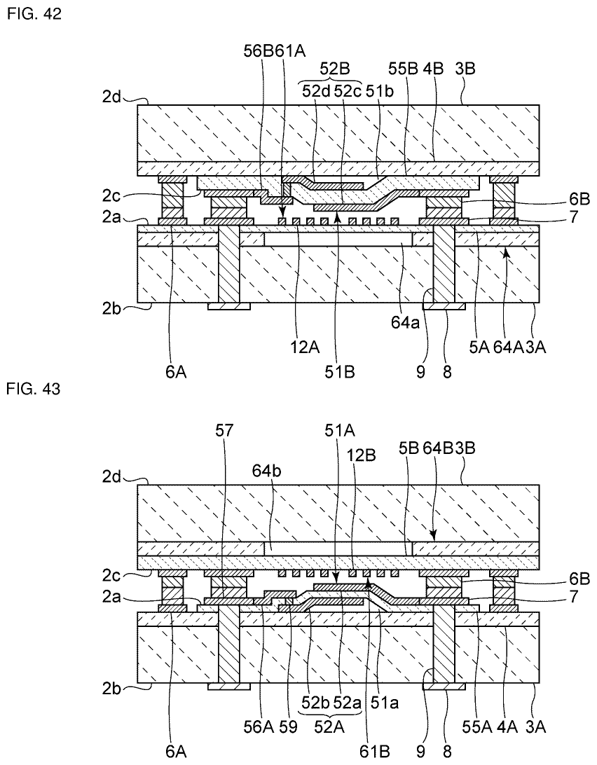

FIG. 42 is a schematic elevational sectional view of an acoustic wave device according to the 18th example embodiment of the present invention.

The present example embodiment is different from the 16th example embodiment in that a first intermediate layer 64A includes a through hole 64a and multiple first resonators include a first resonator 61A configured to be able to use bulk waves in a thickness shear mode as a main mode. The filter apparatus in the present example embodiment has the same or substantially the same structure as in the filter apparatus in the 16th example embodiment except for the above points.

In the first piezoelectric substrate, one of openings of the through hole 64a in the first intermediate layer 64A is closed by the first piezoelectric layer 5A. The other opening of the through hole 64a is closed by the first supporting substrate 3A. Thus, a cavity portion is provided in the first piezoelectric substrate. Instead, for example, the first intermediate layer 64A may be provided with a recessed portion, and the recessed portion may be closed by the first piezoelectric layer 5A. The first IDT electrode 12A in the first resonator 61A overlaps the cavity portion in the first piezoelectric substrate in plan view.

In the present example embodiment, for example, d/p is about 0.5 or less, where d denotes the thickness of the first piezoelectric layer 5A and p denotes an electrode finger pitch in the first IDT electrode 12A. With this structure, it is possible to suitably excite bulk waves in the thickness shear mode.

FIG. 43 is a schematic elevational sectional view of an acoustic wave device according to the 19th example embodiment of the present invention.

The present example embodiment is different from the 15th example embodiment in that a second intermediate layer 64B includes a through hole 64b and multiple second resonators include a second resonator 61B configured to be able to use bulk waves in a thickness shear mode as a main mode. The filter apparatus in the present example embodiment has the same or substantially the same structure as in the filter apparatus in the 15th example embodiment except for the above points.

In the second piezoelectric substrate, one of openings of the through hole 64b in the second intermediate layer 64B is closed by the second piezoelectric layer 5B. The other opening of the through hole 64b is closed by the second supporting substrate 3B. Thus, a cavity portion is provided in the second piezoelectric substrate. Instead, for example, the second intermediate layer 64B may be provided with a recessed portion, and the recessed portion may be closed by the second piezoelectric layer 5B. The second IDT electrode 12B in the second resonator 61B overlaps the cavity portion in the second piezoelectric substrate in plan view.

In the present example embodiment, for example, d/p is about 0.5 or less, where d denotes the thickness of the second piezoelectric layer 5B and p denotes an electrode finger pitch in the second IDT electrode 12B. With this structure, it is possible to suitably excite bulk waves in the thickness shear mode.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter apparatus comprising:
a first piezoelectric substrate including a first main surface and a second main surface opposed to each other;
at least one first resonator including a functional electrode on the first main surface;
a second piezoelectric substrate including a third main surface on a first piezoelectric substrate side and a fourth main surface opposed to the third main surface;
at least one second resonator including a functional electrode on the third main surface;
a support between the first main surface and the third main surface and providing a space between the first main surface and the third main surface; and
a through electrode passing through the first piezoelectric substrate and electrically coupled to any one of the at least one first resonator and the at least one second resonator; wherein
the first piezoelectric substrate includes a first supporting substrate and a first piezoelectric layer stacked on the first supporting substrate, the first main surface including a main surface of the first piezoelectric layer;
the second piezoelectric substrate includes a second supporting substrate and a second piezoelectric layer stacked on the second supporting substrate, the third main surface including a main surface of the second piezoelectric layer; and
a thickness of the first piezoelectric layer is less than a thickness of the second piezoelectric layer.

2. The filter apparatus according to claim 1, wherein a material of the first piezoelectric layer and a material of the second piezoelectric layer are the same.

3. The filter apparatus according to claim 1, further comprising at least one ladder filter including the at least one first resonator and the at least one second resonator; wherein
at least one of the at least one first resonator included in the at least one ladder filter is a series arm resonator of the ladder filter.

4. The filter apparatus according to claim 3, wherein the at least one first resonator includes a plurality of first resonators;
a plurality of first resonators among the plurality of first resonators are included in the at least one ladder filter; and
all of the plurality of first resonators included in the ladder filter are series arm resonators of the ladder filter.

5. The filter apparatus according to claim 1, wherein
at least one ladder filter including the at least one first resonator and the at least one second resonator is provided; and
at least one of the at least one first resonator included in the at least one ladder filter is a parallel arm resonator of the ladder filter.

6. The filter apparatus according to claim 5, wherein
the at least one first resonator includes a plurality of first resonators;
a plurality of first resonators among the plurality of first resonators are included in the at least one ladder filter; and
all of the plurality of first resonators included in the ladder filter are parallel arm resonators of the ladder filter.

7. The filter apparatus according to claim 1, wherein
the functional electrode of the first resonator includes a first IDT electrode on the first piezoelectric layer and including a plurality of first electrode fingers;
the functional electrode of the second resonator includes a second IDT electrode on the second piezoelectric layer and including a plurality of second electrode fingers; and
a thickness of the first IDT electrode and a thickness of the second IDT electrode are different from each other.

8. The filter apparatus according to claim 1, wherein
the functional electrode of the first resonator includes a first IDT electrode on the first piezoelectric layer and including a plurality of first electrode fingers;
the functional electrode of the second resonator includes a second IDT electrode on the second piezoelectric layer and including a plurality of second electrode fingers; and
a material of the first IDT electrode and a material of the second IDT electrode are different from each other.

9. The filter apparatus according to claim 1, wherein
the functional electrode of the first resonator includes a first IDT electrode on the first piezoelectric layer and including a plurality of first electrode fingers;
the functional electrode of the second resonator includes a second IDT electrode on the second piezoelectric layer and including a plurality of second electrode fingers; and
in plan view, an extension direction of the plurality of first electrode fingers intersects an extension direction of the plurality of second electrode fingers.

10. The filter apparatus according to claim 1, wherein
the functional electrode of the first resonator includes a first IDT electrode on the first piezoelectric layer and including a plurality of first electrode fingers;
the functional electrode of the second resonator includes a second IDT electrode on the second piezoelectric layer and including a plurality of second electrode fingers;
the filter apparatus further includes:
a first dielectric film on the first piezoelectric layer and covering the first IDT electrode; and
a second dielectric film on the second piezoelectric layer and covering the second IDT electrode; and
a thickness of the first dielectric film and a thickness of the second dielectric film are different from each other.

11. The filter apparatus according to claim 1, wherein a cut-angle of the first piezoelectric layer and a cut-angle of the second piezoelectric layer are different from each other.

12. The filter apparatus according to claim 1, wherein a material of the first piezoelectric layer and a material used for the second piezoelectric layer are different from each other.

13. The filter apparatus according to claim 1, wherein
the functional electrode of the first resonator includes a first IDT electrode on the first piezoelectric layer and including a plurality of first electrode fingers; and
the functional electrode of the second resonator includes a second IDT electrode on the second piezoelectric layer and including a plurality of second electrode fingers.

14. The filter apparatus according to claim 1, wherein
the first piezoelectric substrate includes a first intermediate layer between the first supporting substrate and the first piezoelectric layer;
the second piezoelectric substrate includes a second intermediate layer between the second supporting substrate and the second piezoelectric layer; and
a thickness of the first intermediate layer and a thickness of the second intermediate layer are different from each other.

15. The filter apparatus according to claim 1, wherein
the first piezoelectric substrate includes a first intermediate layer between the first supporting substrate and the first piezoelectric layer;
the second piezoelectric substrate includes a second intermediate layer between the second supporting substrate and the second piezoelectric layer; and
a material of the first intermediate layer and a material of the second intermediate layer are different from each other.

16. The filter apparatus according to claim 1, wherein
the first piezoelectric substrate includes a first intermediate layer between the first supporting substrate and the first piezoelectric layer;
the second piezoelectric substrate includes a second intermediate layer between the second supporting substrate and the second piezoelectric layer; and
in plan view, a first outer circumferential edge is located outside a second outer circumferential edge, the first outer circumferential edge being an outer circumferential edge of a portion of the through electrode passing through the first piezoelectric layer, and the second outer circumferential edge being an outer circumferential edge of a portion of the through electrode passing through the first intermediate layer.

17. The filter apparatus according to claim 1, wherein, in plan view, a first outer circumferential edge is located outside a third outer circumferential edge, the first outer circumferential edge being an outer circumferential edge of a portion of the through electrode passing through the first piezoelectric layer, and the third outer circumferential edge being an outer circumferential edge of a portion of the through electrode passing through the first supporting substrate.

18. The filter apparatus according to claim 1, wherein
the first piezoelectric substrate includes a first intermediate layer between the first supporting substrate and the first piezoelectric layer;
the second piezoelectric substrate includes a second intermediate layer between the second supporting substrate and the second piezoelectric layer; and
where, in plan view, a first outer circumferential edge is an outer circumferential edge of a portion of the through electrode passing through the first piezoelectric layer, a second outer circumferential edge is an outer circumferential edge of a portion of the through electrode passing through the first intermediate layer, a first point is a point at which a line drawn from a center of the through electrode intersects the first outer circumferential edge, and a second point is a point at which the line intersects the second outer circumferential edge; and
a dimension defined as a distance between the first point and the second point is equal to or smaller than a dimension defined as a thickness of the first intermediate layer.

19. The filter apparatus according to claim 18, wherein
at least one of the at least one first resonator and the at least one second resonator is configured to generate bulk waves in a thickness share mode as a main mode; and
the at least one of the at least one first resonator and the at least one second resonator is configured such that d/p is about 0.5 or less, where d denotes a thickness of the piezoelectric layer and p denotes an electrode finger pitch.

20. The filter apparatus according to claim 1, wherein the first supporting substrate and the second supporting substrate are different from each other in terms of ψ in Euler angles (φ, θ, ψ).
